(19) United States
(12) Patent Application Publication
(10) Pub. No.: US 2025/0066584 A1
(43) Pub. Date: Feb. 27, 2025

(54) PHOTOINITIATORS, COMPOSITIONS, AND METHODS OF FORMING AN OBJECT

(71) Applicant: QUADRATIC 3D, INC., CHARLESTOWN, MA (US)

(72) Inventors: SAMUEL N. SANDERS, ARLINGTON, MA (US); GAVIN R. KIEL, CAMBRIDGE, MA (US); ELANGO KUMARASAMY, ARLINGTON, MA (US)

(21) Appl. No.: 18/945,191

(22) Filed: Nov. 12, 2024

Related U.S. Application Data
(63) Continuation of application No. PCT/US2023/022173, filed on May 13, 2023.
(60) Provisional application No. 63/450,936, filed on Mar. 8, 2023.

(51) Int. Cl. C08K 5/3415

(52) U.S. Cl. CPC C08K 5/3415

(57) ABSTRACT

Photoswitchable photoinitiators comprising a photochromic molecule including one or more substituents at least one of which comprises a substituted or unsubstituted alpha-diketone moiety represented by general formula Ar¹—C(═O)—C(═O)—Ar², wherein Ar¹ and Ar² are the same or different and are independently a substituted or unsubstituted aryl group or a substituted or unsubstituted heteroaryl group. Preferably the photochromic molecule comprises a benzospiropyran molecule, a naphthopyran molecule, or a spironaphthoxazine molecule. Photohardenable compositions, hardenable resin compositions, and methods for forming an object, which photohardenable compositions, hardenable resin compositions, and methods include a photoswitchable photoinitiator described herein, are also disclosed.

### CROSS-REFERENCE TO RELATED APPLICATIONS

This application is a continuation of International Application No. PCT/US2023/022173, filed May 13, 2023, which International Application claims priority to U.S. Provisional Patent Application No. 63/450,936 filed on Mar. 8, 2023, which is hereby incorporated herein by reference in its entirety for all purposes.

### TECHNICAL FIELD OF THE INVENTION

The present invention relates to the technical field of three-dimensional printing and related compositions, materials, methods, and products thereof.

### BRIEF SUMMARY OF THE INVENTION

The present invention includes photoswitchable photoinitiators, photohardenable compositions, hardenable resin compositions, and methods for forming an object, which photohardenable compositions, hardenable resin compositions, and methods include a photoswitchable photoinitiator described herein.

In accordance with one aspect of the present invention there is provided a photoswitchable photoinitiator comprising a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

In accordance with another aspect of the present invention, there is provided a photohardenable composition comprising a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

Photohardenable compositions that display non-Newtonian rheological behavior can be desirable.

In accordance with another aspect of the present invention, there is provided a hardenable resin composition useful for forming an object, the composition comprising: (i) a photohardenable composition; and (ii) a resin component that is hardenable by a thermally driven reaction or mechanism, the resin component comprising a monomer, an oligomer, a pre-polymer, a polymer, or a mixture including at least one the foregoing, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

Photohardenable compositions that display non-Newtonian rheological behavior can be desirable for inclusion in a hardenable resin in accordance with the invention.

Hardenable resin compositions that display non-Newtonian rheological behavior can be desirable.

In accordance with another aspect of the present invention, there is provided a method of forming an object, the method comprising:
(a) providing a volume including a photohardenable composition, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group;
(b) simultaneously or sequentially irradiating one or more selected locations within the volume of the photohardenable composition with light having a first wavelength and light having a second wavelength, wherein light having the first wavelength and light having the second wavelength activate the photoswitchable photoinitiator at the one or more selected locations to induce a crosslinking or polymerization reaction in the photohardenable composition at the intersection of the first and second wavelengths at the one or more selected locations within the volume to at least partially form the object; and
(c) optionally repeating step b, irradiating the photohardenable composition at one or more of the same or different selected locations in the volume until the object is partially or fully formed.

A photohardenable composition that displays non-Newtonian rehological behavior can be desirable for inclusion in a method in accordance with the invention.

In accordance with another aspect of the present invention, there is provided a method of forming an object, comprising:
(a) providing a volume of a hardenable resin composition, wherein hardenable resin composition comprises (i) a photohardenable composition; and (ii) a resin component that is hardenable by a thermally driven reaction or mechanism, the resin component comprising a monomer, an oligomer, a pre-polymer, a polymer, or a mixture including at least one the foregoing, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar1 and Ar2 are the same or different and are independently a substituted or unsubstituted aryl group or a substituted or unsubstituted heteroaryl group;
(b) forming an intermediate object from the hardenable resin composition, wherein formation of the intermediate object comprises:
   (i) simultaneously or sequentially irradiating one or more selected locations within the volume of the hardenable resin composition with light having a first wavelength and light having a second wavelength, wherein light having the first wavelength and light having the second wavelength activate the photoswitchable photoinitiator at the one or more selected locations to induce a crosslinking or polymerization reaction in the photohardenable composition at the intersection of the first and second wavelengths at the one or more selected locations within the volume to at least partially form the object; and
   (ii) optionally repeating step (i) at one or more of the same or different selected locations within the volume of the hardenable resin composition until the intermediate object is formed; and
(c) hardening (e.g., further reacting, further polymerizing, further chain extending) the resin component in the intermediate object by a thermally driven reaction or mechanism to form the object.

A photohardenable composition that displays non-Newtonian rheological behavior can be desirable for inclusion in a method in accordance with the invention.

A hardenable resin composition that displays non-Newtonian rheological behavior can be desirable for inclusion in a method in accordance with the invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

The foregoing, and other aspects and embodiments described herein and contemplated by this disclosure all constitute embodiments of the present invention.

It is to be understood that both the foregoing general description and the following detailed description are exemplary and explanatory only and are not restrictive of the invention as claimed.

Other embodiments will be apparent to those skilled in the art from consideration of the description, from the claims, and from practice of the invention disclosed herein.

### DETAILED DESCRIPTION OF THE INVENTION

Various aspects and embodiments of the present inventions will be further described in the following detailed description.

The present invention includes photoswitchable photoinitiators comprising a photochromic molecule including one or more substituents at least one of which substituents includes a substituted or unsubstituted alpha-diketone moiety described herein, wherein the photochromic molecule comprises a benzospiropyran molecule, a naphthopyran molecule, or a spironaphthoxazine molecule. The present invention also includes photohardenable compositions, hardenable resin compositions, and methods for forming an object, which photohardenable compositions, hardenable resin compositions, and methods include a photoswitchable photoinitiator described herein.

Photoswitchable photoinitiators described herein preferably possess photochromic properties and can be converted to a second form (or active form) upon irradiation with light of a first wavelength, which second form can be converted to an excited state upon irradiation with light of a second wavelength, the second state being capable of inducing a photo-polymerization or photo-cross-linking reaction.

While not wishing to be bound by theory, it is believed that inclusion of a substituent comprising the substituted or unsubstituted alpha-diketone moiety described herein advantageously can expand the spectral range at which the photoswitchable photoinitiator can be excited and can also enhance the photoinitiating ability of the photoswitchable photoinitiator.

In accordance with one aspect of the present invention there is provided a photoswitchable photoinitiator comprising a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

The alpha-diketone moiety can be directly or indirectly attached to the photochromic molecule. Attachment via a single carbon-carbon bond can be preferred.

An aryl group comprises a substituent or functional group derived from an aromatic ring including but not limited to a benzene ring, a naphthalene ring, anthracene ring, indene ring, fluorene ring and others. An aryl group can be substituted or unsubstituted.

A heteroaryl group comprises a substituent or functional group derived from a heteroaryl ring including but not limited to a furan ring, thiophene ring, pyrrole ring, oxazole ring, isooxazole ring, thiazole ring, isothiazole ring, imidazole ring, pyrazole ring, pyrane ring, pyridine ring, pyrazine ring, indole ring, quinoline ring, isoquinoline ring, xanthene ring, carbazole ring, acridine ring, indoline ring, julolidine ring and others. A heteroaryl group can be substituted or unsubstituted.

Among those mentioned above, either one or both of Ar¹ and Ar² can preferably include a phenyl group.

Examples of substituents that can be substituted for a hydrogen atom attached to an aryl group or heteroaryl group in a substituted aryl or heteroaryl group include, but are not limited to, halogen atoms, alkyl, alkoxy, alkylamino, dialkylamino, alkylthio, heterocyclic groups, more specifically, methyl, ethyl, isopropyl, tert-butyl, phenyl, trifluoromethyl, cyano, acetyl, ethoxycarbonyl, carboxyl, carboxylate, amino, methylamino, dimethylamino, ethylamino, diethylamino, isopropylamino, diisopropylamino, cyclohexylamino, dicyclohexylamino, acetylamino, piperidino, pyrrolidyl, —PO₃H, methoxy, ethoxy, propoxy, isopropoxy, butoxy, pentyloxy, phenoxy, hydroxyl, acetoxy, methylthio, ethylthio, isopropylthio, mercapto, acetylthio, thiocyano, methylsulfinyl, methylsulfonyl, dimethylsulfonyl, sulfonate groups, fluorine atom, chlorine atom, bromine atom, iodine atom, trimethylsilyl, triethylsilyl, furyl, thienyl, pyridyl, piperidino, morpholino, pyrrolidyl groups, and the like.

Specific examples of alpha diketone moieties represented by formula (I) include, but are not limited to, the following compounds represented by formula (I-A)-(I-K):

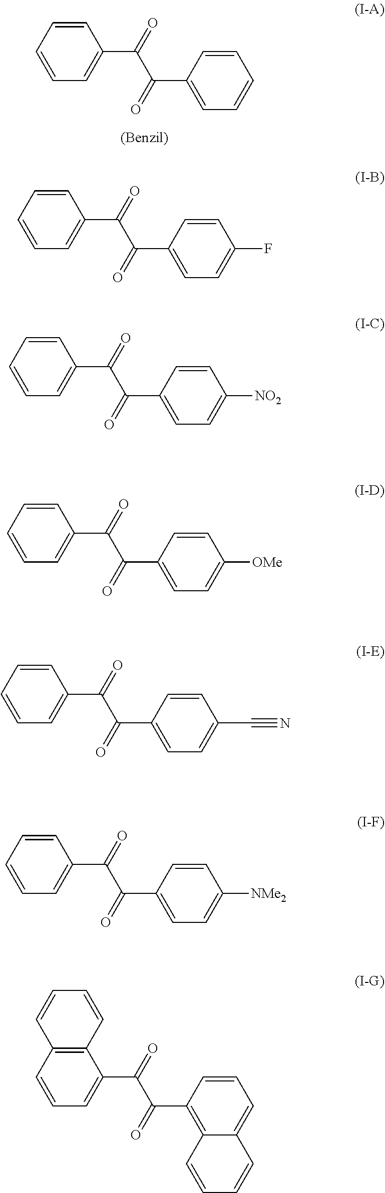

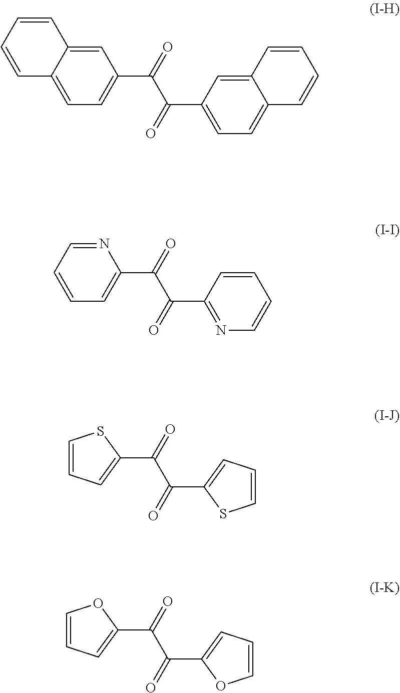 [SMILES: O=C(C(=O)c1ccc2ccccc2c1)c1ccc2ccccc2c1 ; O=C(C(=O)c1ccccn1)c1ccccn1 ; O=C(C(=O)c1cccs1)c1cccs1 ; O=C(C(=O)c1ccco1)c1ccco1]

Optionally Ar¹ and/or Ar² in general formula (I) and any of the compounds represented by formula (I-A)-(I-K) can include one or more substituents on one or both of the aryl or heteroaryl groups, which substituents can be the same or different. Examples of substituents include, but are not limited to, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, a substituted or unsubstituted alcohol group, and those listed above.

As mentioned above, a photochromic molecule can comprise a benzospiropyran molecule including one or more substituents.

Photoswitchable photoinitiators described herein that include a benzospiropyran molecule preferably possess photochromic properties and can be converted to a second form (or active form) upon irradiation with light of a first wavelength, which second form can be converted to an excited state upon irradiation with light of a second wavelength, the second state being capable of inducing cross-linking or photopolymerization of the photohardenable composition. The conversion of the photoswitchable photoinitiators described herein to a second form of the molecule (e.g., an isomer thereof, e.g., for a photochromic molecule having a closed ring structure, to a second form which is an open ring form thereof) is preferably a reversible photochemical structural change. Preferred photoswitchable photoinitiators in accordance with the present invention undergo reversible intramolecular transformations forming the merocyanine isomer (MC) by irradiation (photochromism). Such preferred photoswitchable photoinitiators can function by light activated opening of the benzospiropyran (BSP) ring to form the merocyanine isomer (active form). The active form may subsequently absorb light of a different wavelength to form an excited state of the active form which may subsequently induce photoinitiation. Such preferred photoswitchable photoinitiators may also undergo reversible intramolecular transformations forming MC by heating.

Preferred benzospiropyran photochromic molecules include benzospiropyran molecules represented by general formula (II):

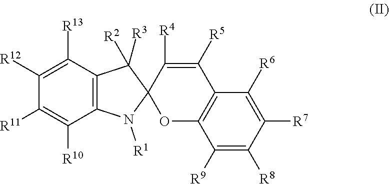

wherein R¹-R¹³ are the same or different and independently represent, for example, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, or a substituted or unsubstituted alcohol group, and
wherein at least one of R¹-R¹³ comprises a substituted or unsubstituted alpha-diketone moiety represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

The alpha-diketone moiety can be directly or indirectly attached to the photochromic molecule. Attachment via a single carbon-carbon bond can be preferred.

For example, a substituted or unsubstituted alpha-diketone moiety can serve as at least one of R¹ to R¹³, being directly attached to a ring of the benzospiropyran molecule by a bond, or it can be indirectly attached to a ring of the benzospiropyran molecule via attachment to a substituent or moiety, which substituent or moiety is attached to a ring of the benzospiropyran molecule as one of R¹ to R¹³.

Optionally, any two adjacent R¹ to R¹³ groups on the benzospiropyran comprise atoms necessary to complete a ring structure linking the two adjacent groups together, in which instance one or more substituted or unsubstituted alpha-diketone moieties can be attached to the ring structure.

Examples of a substituted or unsubstituted alpha-diketone moiety for inclusion in a substituent on a photochromic molecule comprising a benzospiropyran molecule include, but are not limited to, those discussed above.

A photoswitchable photoinitiator described herein that includes a benzospiropyran molecule that includes one or more substituents, at least one of which includes the substituted or unsubstituted alpha-diketone moiety represented by general formula (I), can be prepared utilizing known synthetic techniques. By way of example, and without limitation, a substituted or unsubstituted alpha-diketone moiety represented by general formula (I), may be attached as a substituent to a bromine- or iodine-substituted benzospiropyran molecule via, e.g., palladium-catalyzed cross-coupling reactions, with high yield, mild conditions, and synthetic versatility.

As mentioned above, a photochromic molecule can comprise a naphthopyran molecule including one or more substituents.

Photoswitchable photoinitiators described herein that include a photochromic molecule comprising a naphthopyran molecule preferably possess photochromic properties and can be converted to a second form (or active form) upon irradiation with light of a first wavelength, which second form can be converted to an excited state upon irradiation with light of a second wavelength, the second state being capable of inducing hardening of a photohardenable resin component. The conversion of the photoswitchable photoinitiators described herein to a second form of the molecule (e.g., an isomer thereof, e.g., for a photochromic molecule having a closed ring structure, to a second form which is an open ring form thereof) is preferably a reversible photochemical structural change. Preferred photoswitchable photoinitiators in accordance with the present invention undergo reversible intramolecular transformations forming the open isomeric form (active form) by irradiation (photochromism). Such preferred photoswitchable photoinitiators can function by light activated opening of the naphthopyran ring to form the open isomer form (active form). The active form may subsequently absorb light of a different wavelength to form an excited state of the active form which may subsequently induce photoinitiation. Such preferred photoswitchable photoinitiators may also undergo reversible intramolecular transformations forming the open isomeric form by heating.

Examples of photochromic molecules comprising a naphthopyran molecule for inclusion in a photoswitchable photoinitiator in accordance with the invention include those represented by general formula (III):

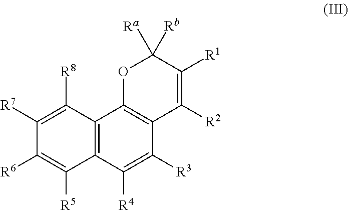

wherein R^{a}, R^{b}, and R¹-R⁸ are the same or different and represent, for example, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, or a substituted or unsubstituted alcohol group; and
wherein at least one of R^{a}, R^{b}, and R¹-R⁸ comprises a substituted or unsubstituted alpha-diketone moiety represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

As discussed above, the alpha-diketone moiety can be directly or indirectly attached to the photochromic molecule. Attachment via a single carbon-carbon bond can be preferred.

For example, a substituted or unsubstituted alpha-diketone moiety can serve as at least one of R^{a}, R^{b}, and R¹-R⁸, being directly attached to a ring of the naphthopyran molecule by a bond, or it can be indirectly attached to a ring of the naphthopyran molecule via attachment to a substituent or moiety, which substituent or moiety is attached to a ring of the naphthopyran molecule as one of R^{a}, R^{b}, and R¹-R⁸.

Optionally, any two adjacent R^{a}, R^{b}, and R¹-R⁸ groups on the naphthopyran molecule can comprise atoms necessary to complete a ring structure linking the two adjacent groups together, in which instance one or more substituted or unsubstituted alpha-diketone moieties can be attached to the ring structure.

It may be preferred for at least one or both of R^{a} and R^{b} to comprise an aryl or heteroaryl group, which groups can be substituted or unsubstituted. More preferably at least one or both of R^{a} and R^{b} include a substituted or unsubstituted alpha-diketone moiety attached thereto. More preferably each of R^{a} and R^{b} can comprise a phenyl group with each phenyl group having a substituted or unsubstituted alpha-diketone moiety attached thereto.

Examples of photoswitchable photoinitiators in accordance with the invention including a naphthopyran molecule represented by general formula (III) include that represented by the following formula (III-A):

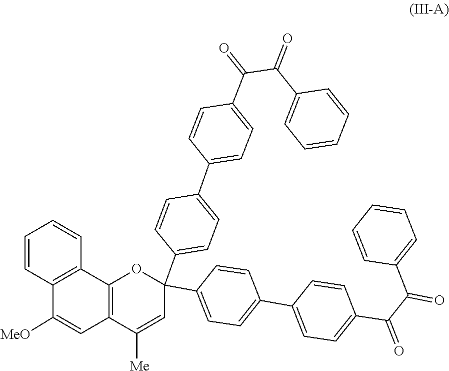

Unless otherwise specified, in formulae included herein, where a substituent may be indicated for one or more positions, but not all positions, a position for which a particular substituent is not indicated, is occupied by hydrogen.

Examples of photochromic molecules comprising a naphthopyran molecule for inclusion in a photoswitchable photoinitiator in accordance with the invention further include those represented by general formula (IV):

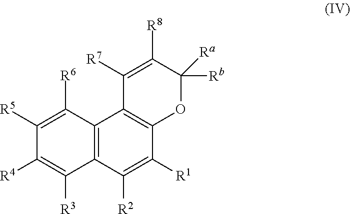

wherein R^{a}, R^{b}, and R¹-R⁸ are the same or different and represent, for example, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, or a substituted or unsubstituted alcohol group; and
wherein at least one of R^{a}, R^{b}, and R¹-R⁸ comprises a substituted or unsubstituted alpha-diketone moiety represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

As discussed above, the alpha-diketone moiety can be directly or indirectly attached to the photochromic molecule. Attachment via a single carbon-carbon bond can be preferred.

For example, a substituted or unsubstituted alpha-diketone moiety can serve as at least one of R^{a}, R^{b}, and R¹-R⁸, being directly attached to a ring of the naphthopyran molecule by a bond, or it can be indirectly attached to a ring of the naphthopyran molecule via attachment to a substituent or moiety, which substituent or moiety is attached to a ring of the naphthopyran molecule as one of R^{a}, R^{b}, and R¹-R⁸.

Optionally, any two adjacent R^{a}, R^{b}, and R¹-R⁸ groups on the naphthopyran molecule can comprise atoms necessary to complete a ring structure linking the two adjacent groups together, in which instance one or more one or more substituted or unsubstituted alpha-diketone moieties can be attached to the ring structure.

It may be preferred for at least one or both of R^{a} and R^{b} to comprise an aryl or heteroaryl group, which groups can be substituted or unsubstituted. More preferably at least one or both of R^{a} and R^{b} include a substituted or unsubstituted alpha-diketone moiety attached thereto. More preferably each of R^{a} and R^{b} can comprise a phenyl group with each phenyl group having a substituted or unsubstituted alpha-diketone moiety attached thereto.

A photoswitchable photoinitiator described herein that includes a naphthopyran molecule that include one or more substituents, at least one of which includes the substituted or unsubstituted alpha-diketone moiety represented by general formula (I), can be prepared utilizing known synthetic techniques. By way of example, and without limitation, a substituted or unsubstituted alpha-diketone moiety described herein may be attached as a substituent to a bromine- or iodine-substituted naphthopyran molecule via, e.g., palladium-catalyzed cross-coupling reactions, with high yield, mild conditions, and synthetic versatility.

As mentioned above, photoswitchable photoinitiator described herein can include photochromic molecule comprising a substituted or unsubstituted spironaphthoxazine molecule.

Photoswitchable photoinitiators described herein that include a photochromic molecule comprising a spironaphthoxazine molecule preferably possess photochromic properties and can be converted to a second form (or active form) upon irradiation with light of a first wavelength, which second form can be converted to an excited state upon irradiation with light of a second wavelength, the second state being capable of inducing hardening of a photohardenable resin component. The conversion of the photoswitchable photoinitiators described herein to a second form of the molecule (e.g., an isomer thereof, e.g., for a photochromic molecule having a closed ring structure, to a second form which is an open ring form thereof) is preferably a reversible photochemical structural change. Preferred photoswitchable photoinitiators in accordance with the present invention undergo reversible intramolecular transformations forming the open isomeric form (active form) by irradiation (photochromism). Such preferred photoswitchable photoinitiators can function by light activated opening of the spironaphthoxazine ring to form the open isomer form (active form). The active form may subsequently absorb light of a different wavelength to form an excited state of the active form which may subsequently induce photoinitiation. Such preferred photoswitchable photoinitiators may also undergo reversible intramolecular transformations forming the open isomeric form by heating.

Examples of photochromic molecules comprising a spironaphthoxazine molecule for inclusion in a photoswitchable photoinitiator in accordance with the invention further include those represented by general formula (V):

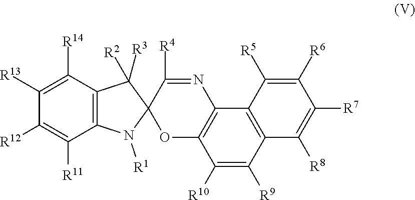

wherein R¹-R¹⁴ are the same or different and represent, for example, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, or a substituted or unsubstituted alcohol group;
wherein at least one of R¹-R¹⁴ comprises a substituted or unsubstituted alpha-diketone moiety represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

As discussed above, the alpha-diketone moiety can be directly or indirectly attached to the photochromic molecule. Attachment via a single carbon-carbon bond can be preferred.

For example, a substituted or unsubstituted alpha-diketone moiety can serve as at least one of R¹-R¹⁴, being directly attached to a ring of the spironaphthoxazine molecule by a bond, or it can be indirectly attached to a ring of the spironaphthoxazine molecule via attachment to a substituent or moiety, which substituent or moiety is attached to a ring of the spironaphthoxazine molecule as one of R¹-R¹⁴.

Optionally, any two adjacent R¹-R¹⁴ groups on the spironaphthoxazine molecule can comprise atoms necessary to complete a ring structure linking the two adjacent groups together, in which instance one or more substituted or unsubstituted alpha-diketone moieties can be attached to the ring structure.

It may be preferred for at least one of R¹-R¹⁴ to comprise an aryl or heteroaryl group, which groups can be substituted or unsubstituted. Optionally, in such case, a substituted or unsubstituted alpha-diketone moiety can be attached to attached thereto.

It can be desirable for R¹ in general formula (V) to comprise a substituted or unsubstituted alkyl or aryl (e.g., benzyl, i.e., a benzene ring with an attached CH₂ group).

Examples of photoswitchable photoinitiators in accordance with the invention including a spironaphthoxazine molecule represented by general formula (V) include those represented by the following formula (V-A):

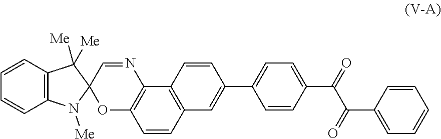

Examples of photochromic molecules comprising a spironaphthoxazine molecule for inclusion in a photoswitchable photoinitiator in accordance with the invention further include those represented by general formula (VI):

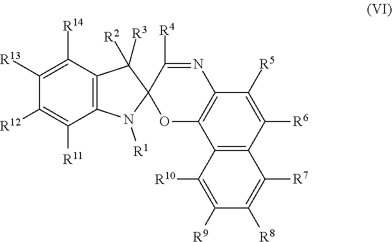

wherein R¹-R¹⁴ are the same or different and represent, for example, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, or a substituted or unsubstituted alcohol group;
wherein at least one of R¹-R¹⁴ comprises a substituted or unsubstituted alpha-diketone moiety represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

As discussed above, the alpha-diketone moiety can be directly or indirectly attached to the photochromic molecule. Attachment via a single carbon-carbon bond can be preferred.

For example, a substituted or unsubstituted alpha-diketone moiety can serve as at least one of R¹-R¹⁴, being directly attached to a ring of the spironaphthoxazine molecule by a bond, or it can be indirectly attached to a ring of the spironaphthoxazine molecule via attachment to a substituent or moiety, which substituent or moiety is attached to a ring of the spironaphthoxazine molecule as one of R¹-R¹⁴.

Optionally, any two adjacent R¹-R¹⁴ groups on the spironaphthoxazine molecule can comprise atoms necessary to complete a ring structure linking the two adjacent groups together, in which instance one or more substituted or unsubstituted alpha-diketone moieties can be attached to the ring structure.

It may be preferred for at least one of R¹-R¹⁴ to comprise an aryl or heteroaryl group, which groups can be substituted or unsubstituted. Optionally, in such case, one or more substituted or unsubstituted alpha-diketone moieties can be attached to attached thereto.

It can be desirable for R¹ in general formula (VI) to comprise a substituted or unsubstituted alkyl or aryl (e.g., benzyl, i.e., a benzene ring with an attached CH₂ group).

A photoswitchable photoinitiator described herein that includes a spironaphthoxazine molecule including one or more substituents attached thereto, at least one of which comprises a substituted or unsubstituted alpha-diketone moiety represented by general formula (I), can be prepared utilizing known synthetic techniques. By way of example, and without limitation, a substituted or unsubstituted alpha-diketone moiety described herein may be attached as a substituent to a chlorine, bromine, or iodine-substituted spironaphthoxazine molecule via, e.g., palladium-catalyzed cross-coupling reactions, with high yield, mild conditions, and synthetic versatility.

In accordance with another aspect of the present invention, there is provided a photohardenable composition comprising a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photoswitchable photoinitiator comprising a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group.

It can be preferred for the substituted or unsubstituted alpha-diketone moiety to comprise alpha-diketone moiety represented any of formulae (I-A) to (I-K) above. As mentioned above, optionally any of the hydrogens attached to a ring member in any of the formulae can instead include a substituent or moiety in place thereof.

As discussed below, photohardenable composition that displays non-Newtonian rheological behavior can be desirable or preferred.

A photohardenable composition can optionally further include a coinitiator.

A photohardenable composition can optionally further include a sensitizer.

Optionally, the photohardenable composition can include a combination including one or more coinitiators and/or one or more sensitizers.

Several considerations in selecting a particular photoswitchable photoinitiator for inclusion in a photohardenable composition or method in accordance with the present invention include, by way of example, but not limited to, the absorption spectra and Amax of the molecule and of its second form, the solubility of the photoswitchable photoinitiator in the photohardenable resin component, the photosensitivity of the second form of the photoswitchable photoinitiator, the amount of initial concentration of the second form in the monomer solution, the stability of the photoswitchable photoinitiator and the reduction and oxidation potentials of the second form of the photoswitchable photoinitiator.

Photoswitchable photoinitiators and photohardenable compositions in accordance with the present invention are particularly suitable for use in the methods of the present invention for forming three-dimensional objects because the photoswitchable photoinitiator molecule in its closed form and the photoinitiator molecule in its activated second form (e.g., the open form) have sufficiently distinct absorption spectra that once the closed form of the molecule is converted to its open form, the open form absorbs in a wavelength region where the closed form is substantially non-absorbing. In this way, the open form can be independently excited with the second wavelength without causing unintended excitation of the closed form by the second wavelength. The second wavelength can excite the open form to generate free radicals or otherwise induce a desired crosslinking or polymerization reaction in the photohardenable resin component once the open form has been generated by exposure to the first wavelength.

A photohardenable resin component suitable for use in the photohardenable composition includes any resin (e.g., a monomer, an oligomer, a pre-polymer, a polymer, or a mixture including at least one the foregoing) that is photohardenable by exposure to light in the presence of a photoinitiator. Examples of photohardenable resin components useful for inclusion in a photohardenable composition in accordance with the present invention include ethylenically unsaturated compounds and, more specifically, a polyethylenically unsaturated compounds. These compounds include both monomers having one or more ethylenically unsaturated groups, such as vinyl or allyl groups, and polymers having terminal or pendant ethylenic unsaturation. Such compounds are well known in the art and include, but are not limited to, acrylic and methacrylic esters of polyhydric alcohols such as trimethylolpropane, pentaerythritol, and the like; and acrylate or methacrylate terminated epoxy resins, acrylate or methacrylate terminated polyesters, etc. Representative examples include, but are not limited to, ethylene glycol diacrylate, ethylene glycol dimethacrylate, trimethylolpropane triacrylate (TMPTA), pentaerythritol tetraacrylate, pentaerythritol tetramethacrylate, dipentaerythritol hydroxypentacrylate (DPHPA), hexanediol-1,6-dimethacrylate, and diethyleneglycol dimethacrylate. Preferred examples include, but are not limited to, a urethane acrylate or a urethane methacrylate.

A photohardenable resin component can optionally comprise one or more multifunctional acrylate monomers. Dipentaerythritol pentaacrylate, a pentafunctional acrylic monomer available from Sartomer as SR399 is an example of a photohardenable resin component that may be desirable for inclusion in a hardenable resin composition of the present invention.

Aliphatic urethane acrylates may also be desirable for use as a photohardenable resin component for inclusion in a hardenable resin composition described herein.

Mixtures of multifunctional acrylate monomers, such as dipentaerythritol pentaacrylate (e.g., SR399 from Sartomer), and aliphatic urethane acrylates can also be used.

An acrylate monomer or acrylamide monomer can also be included in a hardenable resin composition to act as a solvent for mixing the photoinitiator in the first resin component. An acrylate monomer may be preferred.

Preferably, the photohardenable resin component included in the photohardenable composition is selected to achieve an optically transparent or clear liquid, which is desirable in processes and systems in which light, e.g., excitation light, is directed into the composition.

As provided herein, a photohardenable compositions in accordance with the present invention can optionally include one or more coinitiators.

Suitable coinitiators include coinitiators which are reducing agents, oxidizing agents, or hydrogen donating compounds.

Examples of coinitiators that may be useful can be selected from among those known in the art and, more particularly, tertiary amines and organoborate salts. Iodonium salts may also be useful, particularly in combination with a borate salt. In certain embodiments, an iodonium salt may also be included in combination with a tertiary amine. Examples of other useful electron donating coinitiators are discussed by Eaton, D. F., “Dye Sensitized Photopolymerization”, Advances in Photochemistry, Vol. 13, pp 427-486.

Representative examples of N,N-dialkylanilines useful in the present invention as coinitiators include 4-cyano-N,N-dimethylaniline, 4-acetyl-N,N-dimethylaniline, 4-bromo-N,N-dimethylaniline, 4-methyl-N, N-dimethylaniline, 4-ethoxy-N,N-dimethylaniline, N,N-dimethylthioanicidine, 4-amino-N,N-dimethylaniline, 3-hydroxy-N, N-dimethylaniline, N,N,N,'N,-tetramethyl-1,4-dianiline, 4-acetamido-N,N-dimethylaniline, 2,6-diethyl-N,N-dimethylaniline, N,N,2,4,6-pentanethylaniline (PMA) and p-t-butyl-N,N-dimethylaniline.

Certain other tertiary amines are also useful coinitiators including triethylamine, triethanolamine, N-methyldiethanolamine, 2-ethyl-4-(dimethylamino) benzoate, 2-ethylhexyl-4-(dimethylamino) benzoate, etc.

Another class of useful coinitiators includes alkyl borate salts such as ammonium salts of borate anions of the formula BR^{a} R^{b} R^{c} R^{d} wherein R^{a}-R^{d} are independently selected from the group consisting of alkyl, aryl, alkaryl, allyl, aralkyl, alkenyl, alkynyl, alicyclic and saturated or unsaturated heterocyclic groups. Representative examples of alkyl groups represented by R^{a}-R^{d} are methyl (Me), ethyl, propyl, butyl, pentyl, hexyl, octyl, stearyl, etc. The alkyl groups may be substituted, for example, by one or more halogen, cyano, acyloxy, acyl, alkoxy or hydroxy groups. Representative examples of aryl groups represented by R^{a}-R^{d} include phenyl, naphthyl and substituted aryl groups such as anisyl and alkaryl such as methylphenyl, dimethylphenyl, etc. Representative examples of aryl groups represented by R^{a}-R^{d} include benzyl. Representative alicyclic groups include cyclobutyl, cyclopentyl, and cyclohexyl groups. Examples of an alkynyl group aryl propynyl and ethynyl, and examples of alkenyl groups include a vinyl group. Preferably, at least one but not more than three of R^{a}, R^{d}, R^{c}, and R^{d} is an alkyl group. Each of R^{a}, R^{b}, R^{c}, and R^{d} can contain up to 20 carbon atoms, and they typically contain 1 to 7 carbon atoms. More preferably R^{a}-R^{d} are a combination of alkyl group(s) and aryl-group(s) or aralkyl group(s) and still more preferably a combination of three aryl groups and one alkyl group, i.e., an alkyltriphenylborate, e.g., but not limited to, a butyltriphenyl borate.

As mentioned herein, a photohardenable composition in accordance with the present invention can optionally include a synergist. Non-limiting examples of synergists include an amine, a thiol, a thioether, a mercaptan, a silane, an organoborate compound, a diaryliodonium salt, a triarylsulfonium salt. A preferred example of a suitable synergist is butyryl choline butyltriphenylborate. Another preferred example of a suitable synergist is N-methyldiethanolamine. When included in a photohardenable composition, a synergist, in combination with the photoswitchable photoinitiator, can facilitate photoinitiation by the photoswitchable photoinitiator active form via, e.g., electron transfer or hydrogen transfer.

Photohardenable compositions and methods in accordance with the present invention preferably include a photohardenable composition that displays non-Newtonian rheological behavior advantageously where this rheological behavior can facilitate forming an object in a volume of a photohardenable composition described herein upon exposure to at least two different wavelengths of excitation light wherein the object remains at a fixed position or is minimally displaced in the volume of the unhardened photohardenable composition during formation. Minimal displacement refers to displacement of the object being formed during its formation in the volume that is acceptable for precisely producing the intended part geometry.

Photohardenable compositions and methods in accordance with the present invention can preferably include a photohardenable composition that displays non-Newtonian rheological behavior that advantageously can also facilitate separation of the formed object from the unhardened photohardenable composition upon application of stress. While not wishing to be bound by theory, upon the application of stress, the apparent viscosity of the non-Newtonian photohardenable composition can drop to a lower value (e.g., the steady shear viscosity) than the static value (e.g., zero shear viscosity or yield stress) allowing the unhardened photohardenable composition to more easily flow off and separate from the object. Examples of such non-Newtonian rheological behavior include but are not limited to pseudoplastic fluid, yield pseudoplastic, Bingham plastic, or Bingham pseudoplastic.

Non-Newtonian rheological behavior can be imparted to the photohardenable composition by further including one or more reactive components (e.g., urethane acrylate oligomers, urethane methacrylate oligomers, acrylated or methacrylated polyurethanes, acrylated or methacrylated polyurethane-ureas, acrylated or methacrylated polyesters, acrylated or methacrylated polyamides, acrylate- or methacrylate-functional block copolymers, alkenyl- or alkynyl-functional urethane oligomers, alkenyl- or alkynyl-functional polyurethanes, alkenyl- or alkynyl-functional polyurethane-ureas, alkenyl- or alkynyl-functional polyesters, alkenyl- or alkynyl-functional polyamides, alkenyl- or alkynyl-functional block copolymers, thiol-functional urethane oligomers, thiol-functional polyurethanes, thiol-functional polyurethane-ureas, thiol-functional polyesters, thiol-functional polyamides, thiol-functional block copolymers) in the photohardenable resin component and/or by further adding one or more nonreactive additives (e.g., but not limited to, one or more thixotropes and/or rheology modifiers) to the photohardenable composition. Selection of the one or more of reactive components and the amounts thereof for addition to the photohardenable resin component to impart non-Newtonian rheological behavior thereto is within the skill of the skilled artisan in the relevant art without undue experimentation. Similarly, selection of nonreactive additives and the amount(s) thereof for addition to the photohardenable composition to impart non-Newtonian rheological behavior thereto is within the skill of the skilled artisan of the relevant art without undue experimentation.

For photohardenable composition in accordance with the present invention, preferred steady shear viscosities are less than 30,000 centipoise, more preferably less than 10,000 centipoise, and most preferably less than 1,000 centipoise. (Steady shear viscosity refers to the viscosity after the thixotrope network has broken up.)

### Fillers

Optionally, photohardenable compositions in accordance with the present invention can further include one or more fillers. Fillers can be included in an amount greater than 0 to about 90 weight percent, the amount being determined by the purpose for the filler and the desired end use characteristics for the intended three-dimensional object. Advantageously, fillers may be selected to maintain the optical transparency of the photohardenable or hardenable composition, e.g., by controlling particle size to be substantially less than the excitation wavelengths or by matching the refractive indices of the filler and matrix to reduce optical scatter.

Fillers may be used to modify the properties of the hardened photohardenable composition, for example the stiffness, strength, toughness, impact resistance, resistance to creep, resistance to fatigue, mechanical energy return, mechanical loss tangent, glass transition temperature, thermal degradation temperature, thermal conductivity, thermal resistance, moisture uptake, electrical conductivity, static dissipation, dielectric constant and loss tangent, density, refractive index, optical dispersion, opacity to ionizing radiation, and resistance to ionizing radiation. Fillers may also be used to modify the properties of the liquid photohardenable composition, such as rheological properties such as viscosity and thixotropy and optical properties such as refractive index. Examples of fillers include but are not limited to silica, alumina, zirconia; silicates glasses such as soda-lime glass, borosilicate glass, sodium silicate glass, lead glass, aluminosilicate glass, barium glass, thorium glass, glass ceramics; chalcogenide glasses; glass microspheres and microbubbles; nanoclays such as laponite, montmorillonite, bentonite, kaolinite, hectorite, and halloysite; calcium phosphate minerals such as hydroxyapatite, mineral fillers such as chalk, rock dust, slag dust, fly ash, hydraulic cement, loess, limestone, kaolin, talc, and wollastonite. Examples of particle size ranges include but are not limited to less than 10 microns, less than 1 micron, 10 nm to 500 nm, 10 nm to 90 nm, 40 nm to 70 nm. Smaller particles sizes, in particular sizes less than about 100 nm, may be beneficial to provide high optical clarity of the liquid composition to better facilitate printing. Controlling the particle size distribution, for example monodisperse, bimodal, or trimodal distributions of sizes, may be beneficial to control rheological properties, increase filler weight percent, or modify the properties of the photohardenable composition.

### Other Additives

As mentioned above, photohardenable compositions in accordance with the present invention can further include one or more additives. Examples of additives include, but are not limited to, a thixotrope/rheology modifier, a defoamer, a stabilizer, an oxygen scavenger, and a non-reactive solvent diluent. Any additive can be a single additive or a mixture of additives. For example, a thixotrope can comprise a single thixotrope or a mixture of two or more thixotropes.

Additives are preferably selected so that they do not react with the hardenable resin component, photoinitiator, or any other additives that may be included in photohardenable compositions.

### Thixotrope/Rheology Modifier

Thixotropes and rheology modifiers suitable for inclusion in a photohardenable composition described herein include, for example and without limitation, urea derivatives; modified urea compounds such as Rheobyk 410 and Rheobyk-D 410 available from BYK-Chemie GmbH, part of the ALTANA Group; fumed metal oxides (also referred to as pyrogenic metal oxides) including for example, but not limited to, fumed silica, fumed alumina; zirconia; precipitated metal oxides including for example, but not limited to, precipitated silica, precipitated alumina; unmodified and organo-modified phyllosilicate clays; dimer and trimer fatty acids; polyether phosphates; oxidized polyolefins; hybrid oxidized polyolefins with polyamide; alkali soluble/swellable emulsions; cellulosic ethers; hydrophobically-modified alkali soluble emulsions; hydrophobically-modified ethylene oxide-based urethane; sucrose benzoate; ester terminated polyamides; tertiary amide terminated polyamides; polyalkyleneoxy terminated polyamides; polyether amides; acrylamidomethyl-substituted cellulose ester polymers; polyethyleneimine; polyurea; organoclays; hydrogenated castor oil; organic base salts of a clay mineral (e.g., montmorillonite) and other silicate-type materials; aluminum, calcium, and zinc salts of fatty acids, such as lauric or stearic acid.

See U.S. Pat. No. 6,548,593 of Merz, et al., issued Apr. 15, 2003, and U.S. Pat. No. 9,376,602 of Walther, et al. issued Jun. 28, 2016, which are hereby incorporated herein by reference in their entireties, for information relating to urea derivatives that may be useful as thixotropes.

Thermally reversible gellants such as ester terminated polyamides, tertiary amide terminated polyamides, polyalkyleneoxy terminated polyamides, and polyether amides, and combinations thereof, may be desirable for us as thixotropes. Examples include Crystasense LP1, Crystasense LP2, Crystasense LP3, Crystasense MP, Crystasense HP4, Crystasense HP5, Rheoptima X17, Rheoptima X24, Rheoptima X38, Rheoptima X58, Rheoptima X73, and Rheoptima X84 available from Croda. Crystasense HP-5 is a preferred example of a thixotrope.

Metal oxides that have been surface-treated to impart dispersibility characteristics compatible with the hardenable resin component may be desirable for use as thixotropes.

A thixotrope can be included in a photohardenable composition described herein in an amount in a range, for example, from about 0.05 weight percent to about 15, from about 0.5 weight percent to about 15 weight percent, from about 0.5 to about 10 weight percent, from about 0.5 weight percent to about 10 weight percent, from about 1 to about 10 weight percent, of the photohardenable composition. Other amounts may also be determined to be useful.

A thixotrope is preferably included in a photohardenable composition in an amount effective to at least partially restrict movement of the three-dimensional object or one or more regions thereof in the photohardenable composition during formation.

More preferably, the thixotrope is included in the photohardenable composition in an amount effective to at least partially restrict movement of the three-dimensional object suspended (without contact with a container surface) in the volume of the photohardenable composition during formation. Most preferably the position of the object in the volume of the photohardenable composition remains fixed position during formation of the object.

### Defoamer

A defoamer can be included to aid in removing bubbles introduced during processing and handling. A preferred defoamer is BYK 1798 (a silicone based defoamer) available from BYK-Chemie GmbH, part of the ALTANA Group.

### Stabilizer

A stabilizer can be included to improve shelf-life of the photohardenable composition and/or to control the level of cure and/or spatial resolution during printing. An example of preferred stabilizer is TEMPO (2,2,6,6-tetramethylpiperidinooxy free radical available from Sigma-Aldrich). Examples of other stabilizers include, but are not limited to, hindered phenols such as butylated hydroxytoluene; hydroquinone and its derivatives such as hydroquinone methyl ether; hindered amine light stabilizers; alkylated diphenylamines; and phosphite esters.

### Oxygen Scavenger

An oxygen scavenger can be included to react with oxygen (e.g., singlet oxygen, dissolved oxygen) present in the photohardenable composition.

### Non-Reactive Solvent Diluent

A non-reactive solvent diluent can be included. Examples include, but are not limited to, acetone, amyl acetate, n-butanol, sec-butanol, tert-butanol, butyl acetate, cyclohexanone, decane, dimethylacetamide, dimethylformamide, dimethylsulfoxide, dipropylene glycol, dipropylene glycol methyl ether, ethanol, ethyl acetate, ethylene glycol, glycerol, heptane, isopropanol, isopropyl acetate, methyl ethyl ketone, N-methyl pyrrolidone, propylene carbonate, propylene glycol, propylene glycol diacetate, tetrahydrofuran, tripropylene glygol methyl ether, toluene, water, xylenes.

### Thermally Activated Radical Initiator

It may also be desirable to include a thermally activated radical initiator in a photohardenable composition. Thermally activated radical initiator examples include but are not limited to 2,2′-azobis(2-methylpropionitrile), 1,1′-azobis(cyclohexanecarbonitrile), 2,2′-azobis[N-(2-carboxyethyl)-2-methylpropionamidine] n-hydrate, 2,2′-azobis[2-methyl-N-(2-hydroxyethyl)propionamide], organic peroxides, inorganic peroxides, peroxydisulfate salts.

### Second Light-Activated Photoinitiator

Optionally, a photohardenable composition can further include a photoinitiator. Preferably such photoinitiator is not appreciably responsive to light of a first wavelength or second wavelength. Inclusion of a photoinitiator can be desirable in connection with optional post-processing that includes, for example, a post-curing step involving exposure of the printed object to light, preferably in the UV range, after printing. A preferred example of a photoinitiator is Omnirad 184 (1-hydroxycyclohexyl-phenyl ketone) available from IGM. (Omnirad 184, IGM Resins, CAS NO. 947-19-3)

The nature of the monomer, the amount of the photoswitchable photoinitiator and, when applicable, a coinitiator and/or a sensitizer, in photohardenable compositions in accordance with the present invention will vary with the particular use of the compositions, the emission characteristics of the exposure sources, the development procedures, the physical properties desired in the polymerized product and other factors.

Examples of photohardenable compositions in accordance with certain aspects of the invention including one or more coinitiators and/or sensitizers will generally have compositions which fall within the following compositional ranges in parts by weight [based on 100 parts total]:
Photohardenable resin component about 10 to about 99.9999
Photoswitchable photoinitiator about 0.0001 to about 0.5, including, for example, but not limited to, e.g., about 0.0001 to about 0.1, about 0.0001 to about 0.05, about 0.0001 to about 0.02, about 0.0001 to about 0.01, about 0.0001 to about 0.009, about 0.0001 to about 0.005, from about 0.0001 to about 0.0025, etc.
Co-initiator (optional) about 0.001 to about 10 including, for example, but not limited to, about 0.001 to about 7.5, about 0.001 to about 5, about 0.001 to about 2.5, about 0.001 to about 1, about 0.001 to about 0.5, from about 0.001 to about 0.25, etc.
Sensitizer (optional) about 0.1 to 1, including, for example, but not limited to, about 0.1 to about 0.75, about 0.1 to about 0.5, about 0.1 to about 0.25, etc.

Examples of photohardenable compositions in accordance with certain aspects the invention not including one or more coinitiators and/or sensitizers will generally have compositions which fall within the following compositional ranges in parts by weight [based on 100 parts total]:
Photohardenable resin component about 10 to 99.9999
Photoswitchable photoinitiator about 0.0001 to about 0.5, including, for example, but not limited to, e.g., about 0.0001 to about 0.1, about 0.0001 to about 0.05, about 0.0001 to about 0.02, about 0.0001 to about 0.01, about 0.0001 to about 0.009, about 0.0001 to about 0.005, from about 0.0001 to about 0.0025, etc.
Co-initiator (optional) about 0.001 to about 10 including, for example, but not limited to, about 0.001 to about 7.5, about 0.001 to about 5, about 0.001 to about 2.5, about 0.001 to about 1, about 0.001 to about 0.5, from about 0.001 to about 0.25, etc.

When a synergist is optionally further included in a photohardenable composition, it can be included in a compositional range in part by weight [based on 100 parts total] set forth above.

The weight percent of the photohardenable resin component in the above exemplary compositions can be less than 10 weight percent, e.g., less than five weight percent, less than 3 weight percent, less than 2 weight percent, or one weight percent or less, in some cases such as printing of hydrogels where the remainder of the resin is then comprised of non-reactive components that are suspended within the final photohardened resin.

In accordance with another aspect of the present invention, there is provided a hardenable resin composition useful for forming an object, the composition comprising:
(i) a photohardenable composition, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photoswitchable photoinitiator comprising a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group; and
(ii) a resin component that is hardenable by a thermally driven reaction or mechanism, the resin component comprising a monomer, an oligomer, a pre-polymer, a polymer, or a mixture including at least one of the foregoing.

It can be preferred for the substituted or unsubstituted alpha-diketone moiety to comprise alpha-diketone moiety represented any of formulae (I-A) to (I-K) above. As mentioned above, optionally any of the hydrogens attached to a ring member in any of the formulae can instead include a substituent or moiety in place thereof.

Photohardenable compositions that display non-Newtonian rheological behavior can be desirable for inclusion in a hardenable resin in accordance with the invention.

Hardenable resin composition that display non-Newtonian rheological behavior can be desirable.

A hardenable resin composition in accordance with the present invention can optionally further include any one or more of a thixotrope; a stabilizer; a light blocker comprising a light absorbing pigment or dye; a non-reactive solvent diluent; a filler; a defoamer; an oxygen scavenger; a catalyst; and a thermal radical initiator. Other additives may alternatively or additionally be included. Additional information concerning additives is provided above.

A photohardenable composition included in a hardenable resin composition in accordance with the invention preferably comprises a photohardenable composition described herein.

A hardenable resin composition in accordance with the invention includes a resin component that is hardenable by a thermally driven reaction or mechanism. Examples of preferred thermally driven reactions or mechanisms include, but are not limited to, heating (e.g., the direct or indirect application of heat or thermal energy, irradiation with microwaves, irradiation with UV, visible, or infrared light for purpose of heating). A resin component can comprise a monomer, an oligomer, a pre-polymer, a polymer, or a mixture including at least one of the foregoing.

Inclusion of one or more resin components that can be hardened by a thermally driven reaction or mechanism in the hardenable resin composition described herein can facilitate or enable formation of articles with characteristics and/or performance properties that can be suitable for end-use applications for articles formed from a resin including a photohardenable composition without the resin component may not be suitable. Examples of added properties that may be modified by the inclusion of the second resin component include, for example, but are not limited to, mechanical, thermal, electrical, dielectric, chemical resistance, moisture resistance, and biocompatibility properties. Examples include improved mechanical properties including increased tensile strength and modulus, flexural strength and modulus, compressive strength and modulus, impact strength, hardness, wear resistance, fatigue resistance, fracture toughness; improved thermal properties including increased glass transition temperature, increased heat deflection temperature, increased thermal degradation temperature, or reduced coefficients of thermal expansion; reduced moisture or solvent uptake; improved radiation resistance; improved fire resistance, flame retardancy, or char yield; improved dielectric performance (e.g., reduced dielectric constant, reduced dielectric loss constant, or increased breakdown voltage); or improved optical properties (e.g., increased refractive index).

Possible post curing treatments for photohardenable compositions include but are not limited to application of light, heat, electron beam, time (aging), and humidity, and combinations of multiple such treatments in tandem or sequence. Light-based post cure treatments for photohardenable compositions for 3D printing are commonly used and involve providing additional light exposure (e.g., LEDs, sunlight, medium pressure mercury lamps, or fluorescent lamps) to a “green” printed object, often at somewhat elevated temperature (e.g., 45° C. to 80° C.), and often in a specially constructed device (post cure chamber) to a green object to reinitiate and further propagate photoinitiated polymerization reactions (e.g., free radical polymerization of acrylates and methacrylates; cationic ring opening polymerization of epoxides, oxetanes, and vinyl ethers) to reach higher overall conversion of photopolymerizable reactive groups in the post cured object. Incomplete or inhomogeneous penetration of light into the printed object leading to inhomogeneous cure; little or no efficacy for non-photocurable reactive groups; and requirement of specialized equipment are disadvantages of light-based post curing. The requirement of light penetration into the object is especially problematic in highly colored compositions, filled compositions, and compositions where the photoinitiator does not photobleach.

Examples of suitable resin components include, but are not limited to, polyurethane, polyurethane-urea, and polyurea precursors; epoxy resins and epoxy curing agents; cyanate ester resins and phthalonitrile resins; maleimide resins such as bismaleimide resins, alone or with allyl curing agents; polyimide and polyamide imide precursors including but not limited to polyamic acids (e.g., poly (pyromellitic dianhydride-co-4,4′-oxydianiline) amic acid), polyamide amic acids (e.g., Torlon AI-30 and Torlon AI-50 available from Solvay), amines, acid anhydrides, and isocyanates; norbornene resins such as nadic-anhydride-terminated resins; phenolic resins; and benzoxazine resins.

A hardenable resin composition in accordance with the invention can include, for example, but without limitation, from about 0.5 to about 95, preferably from about 40 to about 95, weight percent photohardenable resin component; from about 0.0001 to about 0.5, including, but not limited to, from about 0.0001 to about 0.05, 0.0001 to about 0.02, from about 0.0001 to less than about 0.02, weight percent photoswitchable photoinitiator; and from about 0.5 to about 95, and preferably from about 15 to about 95, weight percent resin component.

A hardenable resin composition can further include, for example, any one or more of the following:
from about 0.05 to about 15, preferably from about 0.5 to about 10, weight percent thixotrope,
from about 0.005 to about 1 weight percent defoamer,
from about 0.005 to about 10 weight percent light blocker,
from about 0.00005 to about 5 weight percent oxygen scavenger,
from about 0.05 to about 95 weight percent non-reactive solvent diluent,
from about 0.00005 to about 10 weight percent catalyst
from about 0.05 to about 10 weight percent thermally activated radical initiator, and
from about 0.5 to about 95 weight percent filler.

Unless otherwise indicated, specified weight percent amounts are based on the total weight of the hardenable resin composition.

In accordance with another aspect of the present invention, there is provided a method of forming an object, the method comprising:
(a) providing a volume including a photohardenable composition, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group;
(b) simultaneously or sequentially irradiating one or more selected locations within the volume of the photohardenable composition with light having a first wavelength and light having a second wavelength, wherein light having the first wavelength and light having the second wavelength activate the photoswitchable photoinitiator at the one or more selected locations to induce a crosslinking or polymerization reaction in the photohardenable composition at the intersection of the first and second wavelengths at the one or more selected locations within the volume to at least partially form the object; and
(c) optionally repeating step b, irradiating the photohardenable composition at one or more of the same or different selected locations in the volume until the object is partially or fully formed.

Preferably the object at least partially formed in the photohardenable composition remains at a fixed position or is minimally displaced in the unhardened photohardenable composition during formation.

It can be preferred for the substituted or unsubstituted alpha-diketone moiety to comprise alpha-diketone moiety represented any of formulae (I-A) to (I-K) above. As mentioned above, optionally any of the hydrogens attached to a ring member in any of the formulae can instead include a substituent or moiety in place thereof.

Preferably the photohardenable composition comprises a photohardenable composition described herein.

A photohardenable composition that displays non-Newtonian rehological behavior can be desirable for inclusion in a method in accordance with the invention.

Preferably the volume of the photohardenable composition is included within a container wherein at least one or more portions of the container are optically transparent so that the photohardenable composition is accessible by light used to irradiate the photohardenable composition. It can be desirable for the optically transparent portions of the container to also be optically flat.

Examples of power densities for the first wavelength light include power densities in a range from about 0.01 to about 100,000 W/cm². Examples of power densities for the second wavelength light include power densities in a range from about 0.01 to about 100,000 W/cm².

Examples of exposure energies for the first wavelength light include exposure energies in a range from about 0.001 to about 1,000 mJ/cm². Examples of exposure energies for the second wavelength light include exposure energies in a range from about 0.01 to about 100,000 mJ/cm².

Methods in accordance with certain aspects of the present invention including a photohardenable composition that demonstrate non-Newtonian rheological behavior can facilitate forming an object, preferably a three-dimensional object, that is fully suspended in the volume of the photohardenable composition during formation. The ability to have the object fully suspended in the volume during formation advantageously eliminates the need to include support structures of the type used in stereolithography to maintain the geometry/shape of the object during formation (which is sometimes referred to as printing or 3D printing).

For use in forming objects, e.g., three-dimensional objects, it is desired that photohardenable compositions do not harden (e.g., the photohardenable resin component does not undergo polymerization or cross-linking) upon exposure of the photohardenable composition to only the first wavelength or only the second wavelength. In other words, hardening of the photohardenable composition in the volume which is not simultaneously or nearly simultaneously (e.g., due to the closely timed sequential exposure) exposed to both radiations do not polymerize. In particular, in scanning a volume of the photohardenable media, as a result of beams passing through previously exposed areas or planes, there will be numerous points in the volume which are sequentially scanned in any order with the first wavelength radiation and the second wavelength radiation as the structure of the object is defined in the volume of the medium by the intersection of the beams. Some points may also experience multiple exposures to the first wavelength light and/or second wavelength light. Preferably points receiving such multiple sequential (non-simultaneous) exposures do not polymerize.

Preferably the amount of time during which one or more selected locations within the volume are simultaneously or sequentially exposed to the first wavelength light and the second wavelength light is sufficient to induce a desired crosslinking or polymerization reaction in the photohardenable composition at the one or more selected locations and is insufficient to cause alteration or hardening of the photohardenable composition when only one of the first and second wavelengths is present.

Preferably light of the first and light of the second wavelengths are projected into the volume as separate optical projections.

Preferably the direction of the projection of light of the first wavelength is orthogonal to the direction of the projection of the light of the second wavelength.

Preferably the projection of light of the first wavelength comprises a light sheet. The light sheet can desirably comprise a planar configuration of light with opposed major faces with the major faces being parallel to direction in which the light sheet is directed into the volume.

Preferably the projection of light of the second wavelength comprises an optical image that is perpendicular to the direction in which the optical image is projected into the volume. A digital micromirror device (DMD) is preferably utilized in the projection of the optical image.

Preferably the light sheet and optical image intersect in a common plane. It is desirable for the intersection of the light sheet and optical image to be coplanar or substantially coplanar.

An optical image can include any optical projection generated by an optical projection system. Examples of optical images include, without limitation, a patterned or unpatterned two-dimensional image, a line of light, or a single point of light. A two-dimensional image can comprise a cross-sectional plane of the three-dimensional image being printed. A two-dimensional image can represent a cross-sectional slice of an object to be printed. Such cross-sectional slice is typically generated using slicing software, as discussed elsewhere herein.

Examples of light sources of the excitation light that may be suitable for use in methods described herein include, by way of example and non-limitation, lasers, laser diodes, light emitting diodes, light-emitting diodes (LEDs), micro-LED arrays, vertical cavity lasers (VCLs), and filtered lamps. Such light sources are commercially available and selection of a suitable light source can be readily made by one of ordinary skill in the relevant art. LEDs of the type such as Phlatlight LEDs available from Luminus for use with DMDs can be preferred. Other suitable light sources may also be useful.

Optionally, the excitation light can be temporally and/or spatially modulated. Optionally, the intensity of the excitation light can be modulated.

Examples of projection devices for use in the methods described herein may include, but are not limited to, a laser projection system, a liquid crystal display (also referred to herein as “LCD”), a spatial light modulator (also referred to herein as “SLM”) (for example, but not limited to, a digital micromirror device (also referred to herein as “DMD”)), a micro-LED array, a vertical cavity laser array (also referred to herein as “VCL”), a Vertical Cavity Surface Emitting Laser array (also referred to herein as “VCSEL”), a liquid crystal on silicon (also referred to herein as “LCOS”) projector, and a scanning laser system. (Light emitting diode is also referred to herein as “LED”).

An optical image projection system can optionally further include one or more optical components (e.g., projection optics, illumination optics, lenses, lens systems, mirrors, prisms, etc.).

The methods of the invention described herein can further include post-processing. Examples of post-processing steps that may be further included in a method in accordance with the invention include, but are not limited to, one or more of the following: separation of the at least partially hardened composition from the unhardened composition, washing, post-curing (e.g., by light, heat, ionizing radiation, pressure, or simultaneous or sequential combinations of techniques), metrology, freeze-dry processing, critical point drying, and packaging.

In methods in accordance with the invention for forming a three-dimensional object, it is desirable to select a photoswitchable photoinitiator molecule for which the wavelength of first excitation has significant absorption for the first form, and where the second form of the photoinitiator has minimal absorption of the first excitation wavelength. This has two advantages, first, it simplifies exposure in that activation of the photoswitchable photoinitiator can occur without activating the second form thereof to induce a crosslinking or polymerization reaction in the photohardenable resin component. When there is substantial overlap, the intensity of the two radiations must be carefully controlled so as to activate the photoswitchable photoinitiator molecule while minimally activating the second form thereof. Second, it can permit deeper penetration of the volume or layer of the composition as the conversion of the photoswitchable photoinitiator to the second form thereof has the effect of “bleaching” the photoswitchable photoinitiator molecule or making it transparent with respect to the first wavelength radiation.

Preparation of photohardenable compositions in accordance with the invention is conducted in an otherwise known or conventional manner, e.g., a solvent for the monomer may be used to remove the photohardenable composition in the unexposed areas. The monomers used herein most typically are known in the art as are their solvents.

Generally, photoswitchable photoinitiators useful in photohardenable compositions and methods described herein can absorb at about 300 to 550 nm. Other examples of ranges in which the photoswitchable photoinitiator will absorb light include, but are not limited to, from about 350 to about 410 nm, about 375 nm±10 nm, and about 405 nm±10 nm. Depending upon the extinction coefficient for the particular photoswitchable photoinitiator, the conversion to the second form can be induced by exposure to any source which emits in this range, e.g., lasers, light emitting diodes, mercury lamps. Filters may be used to limit the output wavelengths. A non-limiting example of filtered light includes filtered emission from a mercury arc lamp, etc.

The second form of the photoswitchable photoinitiator will preferably absorb in a range of about 450 to 1000 nm and 450 to 850 nm most typically. Other examples of ranges in which the second form of the photoswitchable photoinitiator will preferably absorb include 450 to about 700 nm. This form can be activated by the second excitation light to produce free radicals directly or to produce excitons which undergo electron transfer or hydrogen abstraction (optionally via electron, hydrogen, or energy transfer to coinitiator(s) or synergist(s) in aspects of the invention including one or more coinitiator) by exposure to any second wavelength within this range. For the second excitation, exposures may be accomplished using a laser source, an LED or LED array, the filtered emission from an arc lamp, or other suitable source with emission within the desired wavelength range. argon ion, He—Ne, laser diodes, krypton, frequency-multiplied Nd-YAG etc. Other light sources may be used, optionally with filters to limit output wavelengths, e.g., light emitting diodes, incandescent lamps, halogen lamps, mercury lamps, arc lamps, etc.

Optionally, a photohardenable composition included in a method in accordance with the invention can further include a second light-activated photoinitiator that is preferably not appreciably responsive to light of a first wavelength or second wavelength. Inclusion of a second light-activated photoinitiator can be desirable in connection with an optional post-curing step to be carried out, for example, with UV light after printing as part of any post-processing of the printed object. If a second light-activated photoinitiator is included in a photohardenable composition for post-curing purposes, the method can further include a post curing step comprising exposing the object to light of a third wavelength to further harden the object, the third wavelength being different from the first and second wavelengths. Irradiation with the third wavelength is preferably carried out after the partially hardened part is removed or separated from the volume in which it is formed. It can also be desirable to wash the separated or removed part prior to post-cure irradiation with the third wavelength. When the photoinitiator is UV activatable, the third wavelength is preferable in the ultraviolet range of wavelengths. A third wavelength in a range, for example, from about 240 to about 455 nm, about 240 nm to about 445 nm, from about 240 nm to about 410 nm, or other ranges that are less than the first and second wavelengths can be useful.

It can be desirable for a photohardenable composition and/or a hardenable resin composition included in a method in accordance with the present invention to further include a thermally activated radical initiator.

In accordance with another aspect of the present invention, there is provided a method of forming an object, comprising:
(a) providing a volume of a hardenable resin composition, wherein hardenable resin composition comprises (i) a photohardenable composition; and (ii) a resin component that is hardenable by a thermally driven reaction or mechanism, the resin component comprising a monomer, an oligomer, a pre-polymer, a polymer, or a mixture including at least one the foregoing, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the photoswitchable photoinitiator comprises a photoswitchable photoinitiator comprising a photochromic molecule including one or more substituents at least one of which comprises a substituted or unsubstituted alpha-diketone moiety, wherein the photochromic molecule comprises a benzospiropyran molecule, a naphthopyran molecule, or a spironaphthoxazine molecule, and wherein the substituted or unsubstituted alpha-diketone moiety is represented by general formula (I):

Ar¹—C(═O)—C(═O)—Ar² (I)
wherein Ar¹ and Ar² are the same or different and are independently a substituted or unsubstituted aryl group or a substituted or unsubstituted heteroaryl group;
(b) forming an intermediate object from the hardenable resin composition, wherein formation of the intermediate object comprises:
   (i) simultaneously or sequentially irradiating one or more selected locations within the volume of the hardenable resin composition with light having a first wavelength and light having a second wavelength, wherein light having the first wavelength and light having the second wavelength activate the photoswitchable photoinitiator at the one or more selected locations to induce a crosslinking or polymerization reaction in the photohardenable composition at the intersection of the first and second wavelengths at the one or more selected locations within the volume to at least partially form the object; and
   (ii) optionally repeating step (i) at one or more of the same or different selected locations within the volume of the hardenable resin composition until the intermediate object is formed; and
(c) hardening (e.g., further reacting, further polymerizing, further chain extending) the resin component in the intermediate object by a thermally driven reaction or mechanism to form the object.

Photoswitchable photoinitiators that may be preferred include a benzospiropyran molecule including one or more substituents at least one of which includes a substituted or unsubstituted alpha-diketone moiety, a naphthopyran molecule including one or more substituents at least one of which includes a substituted or unsubstituted alpha-diketone moiety, and a spironaphthoxazine molecule including one or more substituents at least one of which includes a substituted or unsubstituted alpha-diketone moiety.

It can be preferred for the substituted or unsubstituted alpha-diketone moiety to comprise alpha-diketone moiety represented any of formulae (I-A) to (I-K) above. As mentioned above, optionally any of the hydrogens attached to a ring member in any of the formulae can instead include a substituent or moiety in place thereof.

Preferably the photohardenable composition comprises a photohardenable composition described herein.

A photohardenable composition that displays non-Newtonian rheological behavior can be desirable for inclusion in a method in accordance with the invention.

A hardenable resin composition that displays non-Newtonian rheological behavior can be desirable for inclusion in a method in accordance with the invention.

Hardenable resin compositions for inclusion in the method of the invention include hardenable resin compositions in accordance with the invention.

Optionally, a photohardenable composition included in a hardenable composition in a method in accordance with the invention or the hardenable resin composition can further include a second light-activated photoinitiator that is preferably not appreciably responsive to light of a first wavelength or second wavelength. Inclusion of a second light-activated photoinitiator can be desirable in connection with an optional post-curing step to be carried out, for example, with UV light after printing as part of any post-processing of the printed object. If a second light-activated photoinitiator is included in a photohardenable composition for post-curing purposes, the method can further include a post curing step comprising exposing the object to light of a third wavelength to further harden the object, the third wavelength being different from the first and second wavelengths. Irradiation with the third wavelength is preferably carried out after the partially hardened part is removed or separated from the volume in which it is formed. It can also be desirable to wash the separated or removed part prior to post-cure irradiation with the third wavelength. When the photoinitiator is UV activatable, the third wavelength is preferable in the ultraviolet range of wavelengths. A third wavelength in a range, for example, from about 240 to about 455 nm, about 240 nm to about 445 nm, from about 240 nm to about 410 nm, or other ranges that are less than the first and second wavelengths can be useful.

If a second light-activated photoinitiator is further included in the hardenable resin composition, the intermediate object can further be irradiated with a third wavelength before, during, or after the step including further hardening by a thermally-driven reaction or mechanism for hardening.

It can be desirable for photohardenable compositions and hardenable resin composition included in a method in accordance with the present invention to further include a thermally activated radical initiator.

Preferably the volume of the hardenable resin composition is included within a container wherein at least one or more portions of the container are optically transparent so that the photohardenable composition included therein is accessible by light used to irradiate the photohardenable composition. It can be desirable for the optically transparent portions of the container to also be optically flat.

Examples of power densities for the first wavelength light include power densities in a range from about 0.01 to about 100,000 W/cm². Examples of power densities for the second wavelength light include power densities in a range from about 0.01 to about 100,000 W/cm².

Examples of exposure energies for the first wavelength light include exposure energies in a range from about 0.001 to about 1,000 mJ/cm². Examples of exposure energies for the second wavelength light include exposure energies in a range from about 0.01 to about 100,000 mJ/cm².

Methods in accordance with certain aspects of the present invention including a photohardenable composition and hardenable resin composition that demonstrate non-Newtonian rheological behavior can facilitate forming an object, preferably a three-dimensional object, that is fully suspended in the volume of the photohardenable composition during formation. The ability to have the object fully suspended in the volume during formation advantageously eliminates the need to include support structures of the type used in stereolithography to maintain the geometry/shape of the object during formation (which is sometimes referred to as printing or 3D printing).

For use in forming objects, e.g., three-dimensional objects, it is desired that photohardenable compositions do not harden (e.g., the photohardenable resin component does not undergo polymerization or cross-linking) upon exposure of the photohardenable composition to only the first wavelength or only the second wavelength. In other words, hardening of the photohardenable composition in the volume which is not simultaneously or nearly simultaneously (e.g., due to the closely timed sequential exposure) exposed to both radiations do not polymerize. In particular, in scanning a volume of the photohardenable media, as a result of beams passing through previously exposed areas or planes, there will be numerous points in the volume which are sequentially scanned in any order with the first wavelength radiation and the second wavelength radiation as the structure of the object is defined in the volume of the medium by the intersection of the beams. Some points may also experience multiple exposures to the first wavelength light and/or second wavelength light. It is desirable to select photoswitchable photoinitiators which reverse when they are not being exposed to first wavelength light.

Preferably the amount of time during which one or more selected locations within the volume are simultaneously or sequentially exposed to the first wavelength light and the second wavelength light is sufficient to induce a desired crosslinking or polymerization reaction in the photohardenable composition at the one or more selected locations and is insufficient to cause alteration or hardening of the photohardenable composition when only one of the first and second wavelengths is present.

Preferably light of the first and light of the second wavelengths are projected into the volume as separate optical projections.

Preferably the direction of the projection of light of the first wavelength is orthogonal to the direction of the projection of the light of the second wavelength.

Preferably the projection of light of the first wavelength comprises a light sheet. The light sheet can desirably comprise a planar configuration of light with opposed major faces with the major faces being parallel to direction in which the light sheet is directed into the volume.

Preferably the projection of light of the second wavelength comprises an optical image that is perpendicular to the direction in which the optical image is projected into the volume. A digital micromirror device (DMD) is preferably utilized in the projection of the optical image.

Preferably the light sheet and optical image intersect in a common plane. It is desirable for the intersection of the light sheet and optical image to be coplanar or substantially coplanar.

An optical image can include any optical projection generated by an optical projection system. Examples of optical images include, without limitation, a patterned or unpatterned two-dimensional image, a line of light, or a single point of light. A two-dimensional image can comprise a cross-sectional plane of the three-dimensional image being printed. A two-dimensional image can represent a cross-sectional slice of an object to be printed. Such cross-sectional slice is typically generated using slicing software, as discussed elsewhere herein.

Preferably the direction of the projection of a light of the first wavelength is orthogonal to the direction of the projection of an optical image.

Preferably the projection of light of the first wavelength comprises a light sheet. The light sheet can desirably comprise a planar configuration of light with opposed major faces with the major faces being parallel to direction in which the light sheet is directed into the volume.

Preferably the projection of light of the second wavelength comprises an optical image that is perpendicular to the direction in which the optical image is projected into the volume. A digital micromirror device (DMD) is preferably utilized in the projection of the optical image.

Preferably the light sheet and optical image intersect in a common plane. It is desirable for the intersection of the light sheet and optical image to be coplanar or substantially coplanar.

Examples of light sources of the excitation light that may be suitable for use in methods described herein include, by way of example and non-limitation, lasers, laser diodes, light emitting diodes, light-emitting diodes (LEDs), micro-LED arrays, vertical cavity lasers (VCLs), and filtered lamps. Such light sources are commercially available and selection of a suitable light source can be readily made by one of ordinary skill in the relevant art. LEDs of the type such as Phlatlight LEDs available from Luminus for use with DMDs can be preferred. Other suitable light sources may also be useful.

Optionally, the excitation light can be temporally and/or spatially modulated. Optionally, the intensity of the excitation light can be modulated.

Examples of projection devices for use in the methods described herein may include, but are not limited to, a laser projection system, a liquid crystal display (also referred to herein as “LCD”), a spatial light modulator (also referred to herein as “SLM”) (for example, but not limited to, a digital micromirror device (also referred to herein as “DMD”)), a micro-LED array, a vertical cavity laser array (also referred to herein as “VCL”), a Vertical Cavity Surface Emitting Laser array (also referred to herein as “VCSEL”), a liquid crystal on silicon (also referred to herein as “LCOS”) projector, and a scanning laser system. (Light emitting diode is also referred to herein as “LED”).

An optical image projection system can optionally further include one or more optical components (e.g., projection optics, illumination optics, lenses, lens systems, mirrors, prisms, etc.)

The methods of the invention described herein can further include post-processing. Examples of post-processing steps that may be further included in a method in accordance with the invention include, but are not limited to, one or more of the following: separation of the at least partially hardened composition from unhardened composition, washing, post-curing (e.g., by light, heat, ionizing radiation, pressure, or simultaneous or sequential combinations of techniques), metrology, freeze-dry processing, critical point drying, and packaging.

In methods in accordance with the invention for forming a three-dimensional object, it is desirable to select a photoswitchable photoinitiator molecule for which the wavelength of first excitation has significant absorption for the first form, and where the second form of the photoinitiator has minimal absorption of the first excitation wavelength. This has two advantages, first, it simplifies exposure in that activation of the photoswitchable photoinitiator can occur without activating the second form thereof to induce a crosslinking or polymerization reaction in the photohardenable resin component. When there is substantial overlap, the intensity of the two radiations must be carefully controlled so as to activate the photoswitchable photoinitiator molecule while minimally activating the second form thereof. Second, it can permit deeper penetration of the volume or layer of the composition as the conversion of the photoswitchable photoinitiator to the second form thereof has the effect of “bleaching” the photoswitchable photoinitiator molecule or making it transparent with respect to the first wavelength radiation.

Preparation of photohardenable compositions in accordance with the invention is conducted in an otherwise known or conventional manner, e.g., a solvent for the monomer may be used to remove the photohardenable composition in the unexposed areas. The monomers used herein most typically are known in the art as are their solvents.

Generally, it is desirable for photoswitchable photoinitiators described herein to absorb at about 300 to 550 nm in their first form, including for example, but not limited to, from about 350 to about 460 nm, from about 350 to about 455 nm, from about 350 nm to about 445 nm, from about 350 nm to about 410 nm, from about 375 to about 455 nm, from about 375 to about 445 nm, from about 375 nm to about 405 nm. Depending upon the extinction coefficient for the particular photoswitchable photoinitiator, the conversion to the second form can be induced by exposure to any source which emits in this range, e.g., lasers, light emitting diodes, mercury lamps. Filters may be used to limit the output wavelengths. A non-limiting example of filtered light includes filtered emission from a mercury arc lamp, etc.

The second form of the photoswitchable photoinitiator will preferably absorb in a range of about 450 to about 1000 nm and about 450 to about 850 nm most typically. Other examples of ranges in which the second form of the photoswitchable photoinitiator will preferably absorb include about 450 to about 700 nm. This form can be activated by the second excitation light to produce free radicals directly or to produce excitons which undergo electron transfer or hydrogen abstraction (optionally via electron, proton, or energy transfer to coinitiator(s) or synergist(s) in aspects of the invention including one or more coinitiator) by exposure to any second wavelength within this range. For the second excitation, exposures may be accomplished using a laser source, an LED or LED array, the filtered emission from an arc lamp, or other suitable source with emission within the desired wavelength range. argon ion, He—Ne, laser diodes, krypton, frequency-multiplied Nd-YAG etc. Other light sources may be used, optionally with filters to limit output wavelengths, e.g., light emitting diodes, incandescent lamps, halogen lamps, mercury lamps, arc lamps, etc.

It can be desirable for photohardenable compositions and hardenable resin composition included in a method in accordance with the present invention to further include a thermally activated radical initiator.

A printed object prepared from a hardenable resin composition including a resin component that is hardenable by a thermally driven reaction or mechanism can be referred to as a “green” object prior to post-curing including a thermally-driven reaction or mechanism to harden the thermally hardenable resin component).

In a method described herein including a hardenable resin composition, once the intermediate article is formed, it may be removed from the hardenable resin composition, optionally washed, any other modifications optionally made, and then subjected to a thermally driven reaction or mechanism (e.g., heated and/or microwave irradiated) sufficiently to further harden (e.g., by further reacting, further polymerizing, further chain extending) the hardenable resin component and form the article. Additional modifications to the formed article may also be made following the heating and/or microwave irradiating step.

Separation of the at least partially cured material (i.e., intermediate article) from the unhardened composition may be conducted by a number of means known in the art, e.g., gravity draining, sieving, air blade, centrifugation, vibration, or ultrasonic agitation.

Washing may be carried out with any suitable organic or aqueous wash liquid, or combination thereof, including solutions, suspensions, emulsions, microemulsions, etc. Examples of suitable wash liquids include, but are not limited to water, alcohols (e.g., methanol, ethanol. isopropanol. etc.), glycol ethers, benzene, toluene, etc. Wash liquids including a mixture of two or more liquids (e.g., water and an alcohol (e.g., isopropanol) may also be suitable. Such wash solutions may optionally contain additional constituents such as surfactants, etc.

After the intermediate article is formed, optionally washed, etc., as described above, it can be further hardened by a thermally driven reaction or mechanism. Hardening can comprise heating and/or microwave irradiation to further cure the same. Heating may be active heating (e.g., in an oven, such as an electric, gas, or solar oven), or passive heating (e.g., at ambient temperature). Active heating can be more rapid than passive heating and in some embodiments can be preferred. Passive heating, e.g., by maintaining the intermediate at ambient temperature for a sufficient time to effect further cure, can also be desirable. Optionally, heating can comprise heating at a first temperature for a first time period, and then heating at a second temperature for a second time period, and then heating at a third temperature for a third time period, and so on, for any number of temperatures and time periods. The temperatures and time periods may be selected to facilitate evaporation of volatiles from the article without causing damage (e.g., cracks); to facilitate more complete curing of lower temperature curing component(s) to stabilize the article shape prior to subsequent cure of higher temperature curing component(s); or to develop higher thermomechanical properties. Differential scanning calorimetry may assist in determining the temperatures and time periods appropriate for curing, by indicating the temperatures where curing reactions initiate and reach their maximum rates (e.g., in a temperature ramp experiment) as well as indicating how much time is required to complete a curing reaction (e.g., in an isothermal experiment). The time periods can be the same length or different. In certain embodiments, the first temperature can be ambient temperature or greater than ambient temperature, and each subsequent temperature can be greater than the previous. Preferably the maximum temperature is sufficient to completely or substantially completely harden or cure the hardenable resin composition but is less than the degradation temperature, e.g., the 5% mass loss temperature as measured by thermogravimetric analysis. When multiple temperatures are used, the temperature can be ramped, for example, by step-wise increases.

For example, the intermediate may be heated in a stepwise manner at a first temperature in a first range, for example, of from about 70° C. to about 150° C., and then at a second temperature in a second range, for example, from about 150° C. to 200° C. or from about 150° C. to about 250° C., with the duration of each heating depending on the size and shape of the intermediate article. In another embodiment, the intermediate may be cured by a ramped heating schedule, with the temperature ramped from a first temperature (e.g., ambient temperature or a temperature greater than ambient temperature) through a second temperature (e.g., a temperature in a range greater than the first temperature to about, for example, 150° C., and up to a final temperature (e.g., a temperature greater than the second temperature to about, for example, 250° C., at a change in heating rate of, for example, 0.5° C. per minute, to 5° C. per minute.

An object (which may also be referred to herein as an article or a part) formed by a method described herein including a hardening step including a thermally driven reaction or mechanism can be the same as or different from the intermediate article prior to the further hardening including a thermally driven reaction or mechanism. For example, there can be changes between the intermediate article and the article as a result of, for example, shrinkage (e.g., up to 1, 2, 5, 10, 25, or 50 percent by volume), expansion (e.g., up to 1, 2, 5, 10 percent by volume), or possible optional intervening forming steps (e.g., intentional bending, stretching, drilling, grinding, cutting, polishing, or other intentional forming after formation of the intermediate product, but before formation of the subsequent article). The intermediate article can preferably be of the same shape as the article to be formed or can have a shape to be imparted to the article to be formed.

The methods in accordance with various aspects of the invention can further include post-treatment of the three-dimensional object(s) formed.

Examples of post-treatments include, but are not limited to, washing, post-curing (e.g., by light, e-beam, heat, non-ionizing radiation, ionizing radiation, time (aging), pressure, humidity, or simultaneous or sequential combinations of techniques), metrology, labelling or tracking (e.g., by barcode, QR code, or RFID tag), freeze-dry processing, critical point drying, and packaging.

In methods described herein that include light sheets, light sheets can be constructed by means known in the art including, for example, but not limited to, techniques including a laser and a Powell lens, galvanometer, and/or polygon scanning mirror. Alternatively, one or more LEDs can be used as a light source.

Optionally, a method described herein can further include use of a different additional wavelength to force the reverse reaction of the second form of the photoswitchable photoinitiator back to the original/starting form to help avoid hardening of unwanted areas.

As used herein first wavelength, second wavelength, and third wavelength can refer to a range of wavelengths.

In methods described herein, the first wavelength and second wavelength are preferably generated by different light sources or different optical projection or other optical systems.

Methods in accordance with the invention preferably include providing a volume of a photohardenable composition described herein or a hardenable resin composition described herein that is included within a container wherein at least a portion of the container is optically transparent so that the photohardenable composition is accessible by excitation light. Optionally, the entire container is optically transparent.

Optically transparent portions of a container can be constructed from a material comprising, for example, but not limited to, glass, quartz, fluoropolymers (e.g., Teflon FEP, Teflon AF, Teflon PFA), cyclic olefin copolymers, polymethyl methacrylate (PMMA), polynorbornene, sapphire, or transparent ceramic.

Examples of container shapes include, but are not limited to, a cylindrical container having a circular or oval cross-section, a container having straight sides with a polygonal cross-section or a rectangular or square cross-section.

Preferably the optically transparent portion(s) of the container is (are) also optically flat.

Optionally, one or more filters can be added to at least a surface of any optically transparent portions of the container to block undesired light, e.g., room light, to prevent unintentional curing.

Optionally the photohardenable composition is filtered to remove particulates before introduction into the container. Optionally bubbles are removed from the photohardenable composition before or after being introduced into the container. Optionally the photohardenable composition is degassed, purged or sparged with an inert gas before or after being introduced into the container. Optionally the photohardenable composition is maintained under inert conditions, e.g., under an inert atmosphere, during printing. This can prevent introduction of oxygen into the container while the object is being printed or formed.

In the methods described herein, the container may be rotated to provide additional angles of illumination or projection of excitation light into the volume of photohardenable composition contained therein. This can be of assistance in patterning object volumes or surfaces more accurately or it can be used as a means of providing multiple exposure of a given feature from different angles.

In the methods described herein, the container may be stationary while a beam or optical projection of excitation light is being directed into the photohardenable composition.

The methods disclosed herein can also include the use of commercially available optical projection and filtering techniques or systems that employ two or more optical projection methods at once.

Before printing, a digital file of the object to be printed is obtained. If the digital file is not of a format that can be used to print the object, the digital file is then converted to a format that can be used to print the object. An example of a typical format that can be used for printing includes, but is not limited to, an STL file. Typically, the STL file is then sliced into two-dimensional layers with use of three-dimensional slicer software and converted into G-Code or a set of machine commands, which facilitates building the object. See B. Redwood, et al., “The 3D Printing Handbook-Technologies, designs applications”, 3D HUBS B.V. 2018.

Examples of sources of the excitation light source for use in the methods described herein include laser diodes, such as those available commercially, light emitting diodes, DMD projection systems, micro-LED arrays, vertical cavity lasers (VCLs). In some embodiments, the excitation radiation source (e.g., the light source) is a light-emitting diode (LED).

The excitation light can be directed into the volume of photohardenable composition in a continuous or intermittent manner. Intermittent excitation can include random on and off application of light or periodic application of light. Examples of periodic application of light includes pulsing. Excitation can alternatively be applied as a combination of both continuous excitation light and intermittent light, including, for example, the application of intermittent excitation light that is preceded or followed by irradiation with continuous light.

Information that may be useful in connection with the various aspects of the present inventions includes International Patent Application No. PCT/US2022/052157, filed Dec. 7, 2022, of Quadratic 3D, Inc., and International Patent Application No. PCT/US2022/039766, filed Aug. 9, 2022, of Quadratic 3D, Inc., each of the foregoing applications being hereby incorporated herein by reference in its entirety.

Other information concerning optical systems that may useful in connection with the various aspects of the present inventions includes Texas Instruments Application Report DLPA022-July 2010 entitled “DLP™ System Optics”; Texas Instruments “TI DL^{R} Technology for 3D Printing-Design scalable high-speed stereolithography [sic] systems using TI DLP technology” 2016; Texas Instruments “DLP6500 0.65 1018p MVSP Type A DMD”, DLP6500, DLPS040A-October 2014—Revised October 2016; and Y-H Lee, et al., “Fabrication of Periodic 3D Nanostructuration for Optical Surfaces by Holographic Two-Photon-Polymerization”, Int'l Journal of Information and Electronics Engineering, Vol 6, No. 3, May 2016, each of the foregoing being hereby incorporated herein by reference in its entirety.

### EXAMPLES

The examples provided herein are provided as examples and not limitations, wherein a number of modifications of the exemplified compositions and processes are contemplated and within the scope of the present invention.

### Example 1—Preparation of Photoswitchable Photoinitiators

### Synthesis of Bpin-Ben

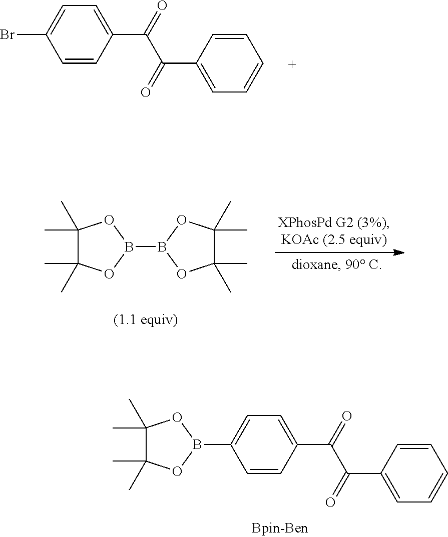

To a 250 mL round-bottom flask was added 1-(4-bromophenyl)-2-phenylethane-1,2-dione (10.0 g, 34.6 mmol, 1.0 equiv), bis (pinacolato) diboron (9.66 g, 38 mmol, 1.1 equiv), XPhos Pd G2 (0.82 g, 1.04 mmol, 0.03 equiv, CAS: 1310584-14-5), potassium acetate (8.5 g, 87 mmol, 2.5 equiv), and a stirbar. The flask was sealed with a rubber septum and placed under an N₂ atmosphere with three vacuum/N₂ cycles. Anhydrous, deoxygenated dioxane (36 mL) was added via syringe and the flask was sealed with electrical tape. The mixture was stirred at 90° C. (heating block temperature) for 12 h, then the mixture was brought to RT and diluted with CH₂Cl₂ (100 mL). The mixture was filtered through a short column of silica gel (40 g). The column was flushed with 20% EtOAc in CH₂Cl₂ (˜200 mL) until no further product was observed by thin layer chromatography. The filtrate was concentrated via rotary evaporation and the crude oil was recrystallized from hexanes (200 mL) at −78° C. to afford Bpin-Ben (1-phenyl-2-(4-(4,4,5,5-tetramethyl-1,3,2-dioxaborolan-2-yl)phenyl)ethane-1,2-dione) (11.0 g, 95%) as pale-yellow solid. ¹H NMR (400 MHz, C₆D₆) δ 8.05-7.96 (m, 4H), 7.90-7.85 (m, 2H), 7.05-6.99 (m, 1H), 6.94-6.88 (m, 2H), 1.07 (s, 12H).

### Synthesis of Compound NO17 Represented by Formula IIIA

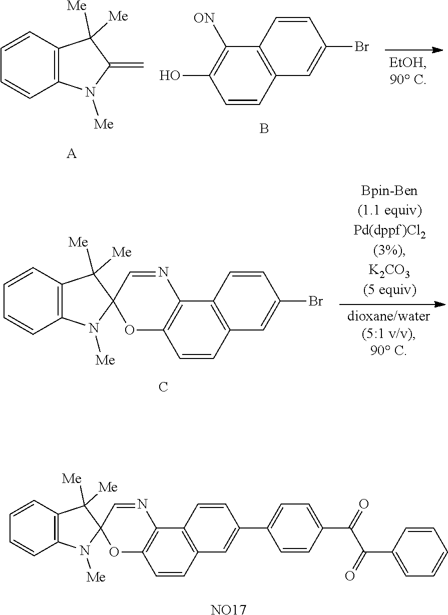

To a 40 mL screw-cap, amber-colored vial was added compound A (2.06 g, 11.9 mmol, 1.00 equiv), compound B (3.00 g, 11.9 mmol, 1.00 equiv), absolute ethanol (12 mL), and a stirbar. The vial was sealed, and the stirred mixture was heated at 90° C. (heating block temperature) for 2 hours. Volatile materials were removed via rotary evaporation at 35° C. To ensure removal of ethanol—small amounts of which affect the subsequent purification—the residue was dissolved in toluene (20-30 mL) and volatile materials were removed via rotary evaporation at 35° C. The residue was subjected to silica gel chromatography (33-50% CH₂Cl₂ in hexanes) to afford the desired bromo-spironaphthoxazine intermediate C as a light brown solid. This solid was analyzed by thin layer chromatography (50% CH₂Cl₂ in hexanes) and used without further purification or characterization.

To a 20 mL screw-cap, amber-colored vial was added bromo-spironaphthoxazine C (50 mg, 0.12 mmol, 1.0 equiv), Bpin-Ben (45 mg, 0.14 mmol, 1.1 equiv), [1,1′-bis(diphenylphosphino)ferrocene]-dichloropalladium (3.0 mg, 0.0037 mmol, 0.03 equiv), potassium carbonate (85 mg, 0.61 mmol, 5.0 equiv), and a stirbar. The vial was sealed and placed under an N₂ atmosphere with three vacuum/N₂ cycles. To this vial was added a deoxygenated 5/1 (v/v) mixture of dioxane/water (3 mL) via syringe, then the vial was sealed with electrical tape. The mixture was stirred vigorously at 90° C. (heating block temperature) for 2 h, then volatile materials were removed via rotary evaporation at 35° C. The residue was subjected to silica gel chromatography (100% CH₂Cl₂) to afford NO17 (45 mg, 68%) as a light green solid. ¹H NMR (400 MHz, C₆D₆) δ 9.10 (d, J=8.8 Hz, 1H), 8.09-8.05 (m, 2H), 8.05-8.00 (m, 2H), 7.70 (d, J=1.8 Hz, 1H), 7.67 (s, 1H), 7.62 (dd, J=8.8, 1.9 Hz, 1H), 7.41-7.33 (m, 3H), 7.12 (dd, J=7.5, 1.8 Hz, 1H), 7.10-7.04 (m, 1H), 7.01-6.95 (m, 2H), 6.92-6.83 (m, 3H), 6.35 (d, J=7.8 Hz, 1H), 2.47 (s, 3H), 1.27 (s, 3H), 1.10 (s, 3H).

### Synthesis of Compound NP31 Represented by Formula IIIA

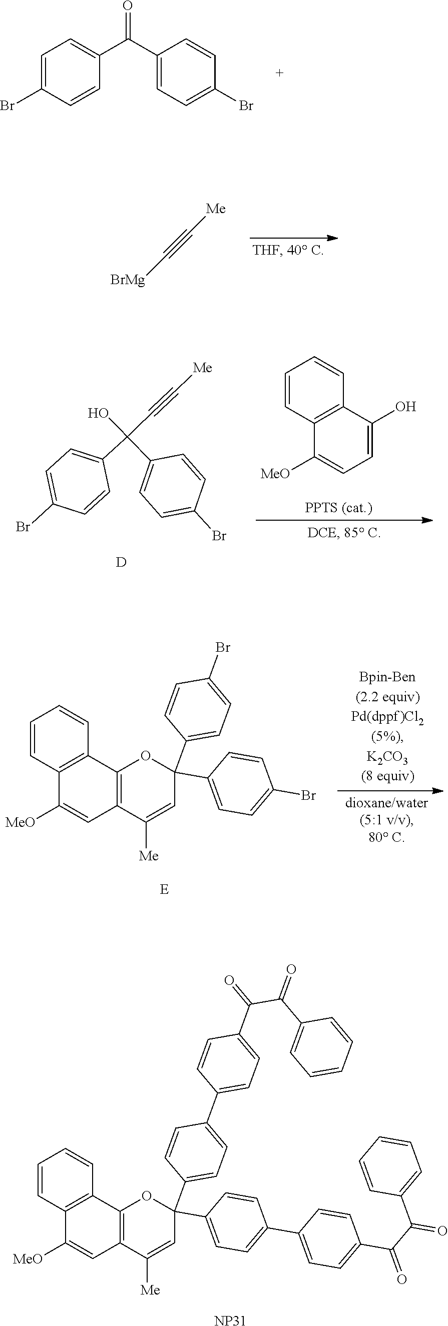

A dry 250 mL two-neck round bottom flask was placed under a nitrogen atmosphere and charged with bis(4-bromophenyl)methanone (2.50 g, 7.35 mmol, 1.0 equiv) and dry THF (25 mL). To this solution was then added propynyl magnesium bromide (0.5 M in THF, 22 mL, 11 mmol, 1.5 equiv) over 5-10 min via syringe. The mixture was heated at 50° C. for 3 hours, after which time TLC indicated complete consumption of starting material. The mixture was carefully quenched with saturated aqueous NH₄Cl (100 mL). The mixture was extracted with ethyl acetate (100 mL) and the organic layer was washed with water (100 mL) and saturated aqueous NaCl (100 mL), dried using sodium sulfate, and filtered. The filtrate was concentrated via rotary evaporation and residual solvent was removed under high vacuum, affording alkynol D (2.5 g) as a pale-yellow oil, which was used in the next step without further purification or characterization.

To a dry 100 mL two neck flask equipped with air condenser and magnetic stirbar was added 4-methoxynaphthalen-1-ol (0.75 g, 4.31 mmol, 1.0 equiv), alkynol D (1.64 g, 4.31 mmol, 1.0 equiv), and pyridinium p-toluenesulfonate (PPTS, 54 mg, 0.05 equiv). The flask was placed under an N₂ atmosphere and charged with anhydrous dichloroethane (40 mL) and trimethyl orthoformate (0.914 g, 2.0 equiv). The mixture was heated to 85° C. (heating block temperature) and maintained at this temperature until one of the starting materials was consumed as determined by TLC. The reaction mixture was cooled to room temperature, volatile materials were removed via rotary evaporation, and the residue was subjected to silica gel chromatography (ethyl acetate/hexanes eluent) to afford bromo-naphthopyran E (1.7 g, 73%) as a pale-yellow solid.

To a 20 mL screw-cap, amber-colored vial equipped with magnetic stir bar was added bromo-naphthopyran E (50 mg, 0.09 mmol, 1.0 equiv), Bpin-Ben (69 mg, 0.21 mmol, 2.2 equiv), [1,1′-bis(diphenylphosphino)ferrocene]-dichloropalladium (3.8 mg, 0.05 equiv) and potassium carbonate (103 mg, 0.75 mmol, 8.0 equiv). The vial was sealed and placed under an N₂ atmosphere with three vacuum/N₂ cycles. To this vial was then added a deoxygenated 5/1 mixture (v/v) of dioxane/water (4 mL) via syringe. The stirred mixture was heated at 80° C. (heating block temperature) for 2-6 h (until TLC indicated reaction completion). Volatile materials were removed via rotary evaporation at 35° C. and the residue was subjected to silica gel chromatography (CH₂Cl₂) to afford NP31 as a pale-yellow solid. 1H NMR (400 MHz, C6D6) δ 8.66 (d, J=8.3 Hz, 1H), 8.44 (d, J=8.4 Hz, 1H), 7.99-7.94 (m, 8H), 7.78-7.73 (m, 4H), 7.46-7.41 (m, 1H), 7.35-7.29 (m, 5H), 7.27-7.21 (m, 4H), 7.07-7.01 (m, 2H), 6.98-6.92 (m, 4H), 6.49 (s, 1H), 6.03 (q, J=1.7 Hz, 1H), 3.43 (s, 3H), 2.04 (d, J=1.5 Hz, 3H).

### Example 2—Base Resin Preparation

12.0 g thixotrope (Crystasense HP-5, Croda) is weighed into a large plastic weigh boat and then poured into a 100-mL 24/40 round bottom flask containing a magnetic stir bar. 50.0 g N,N-dimethylacrylamide (DMAA, Rahn) is added to the flask by 24 mL syringe with a 4-inch 16 G needle. The flask is closed with a rubber septum through which a 1-in 22 G needle is inserted for venting, and the flask is placed in a preheated aluminum heating block on a hot plate set to stir at 105 deg C and 250-300 rpm. After 10-15 min the thixotrope fully dissolves. Next, 50.0 g DMAA is added by syringe to a 0.6-gal polypropylene pail with polypropylene lid. 200.0 g PR013443 (Sartomer) is added by large-bore syringe. 650.0 g Genomer 4259 (Rahn) is added by large-bore syringe. The pail is speedmixed (DAC 2800-1000, Flacktek) at 1100 rpm for 1 min. The HP-5 solution is poured into the pail. The pail is speedmixed at 1100 rpm for a further 1 min.

### Example 3—Preparation of Base Resin Formulation Including a Photoswitchable Photoinitiator

A stock solution of a photoswitchable photoinitiator is prepared by dissolving desired photoswitch in 1:1 v/v mixture of N,N-dimethylacrylamide (DMAA, Rahn) and benzyl acrylate (Beantown chemical) in a 20 mL amber vial such that the final concentration is 1 mg/mL of photoswitch in solvent. 0.3 mL of this photoswitch stock solution is added to 14.7 g of base resin described above to create a resin formulation containing ˜20 ppm of photoswitch. At this point a polymerization synergist is added, for example N-methyldiethanolamine, at a desired concentration (typically 3% by weight). This resin formulation is speedmixed (DAC 2800-1000, Flacktek) at 3000 rpm for 1 min for a total of two times. The formulation is then transferred to 2.5 mL plastic cuvette (Einmal-Küvetten) and capped. The sealed cuvette is centrifuged to remove trapped air bubbles at 4500 rpm for 5 minutes (5804R, Eppendorf).

### Example 4—Evaluation of Photoswitchable Photoinitiation in a Test Resin Formulation under Intersecting Beams of UV and Visible Illumination Light

A centrifuged, bubble free cuvette containing resin prepared according to Example 3 and containing 3% N-methyldiethanolamine is placed in a setup that features two intersecting, approximately collimated coherent light sources. In the case of photoswitchable photoinitiators including a naphthopyran molecule or one of its derivatives, the light sources are (405 nm, 170 mW/cm²) and (532 nm, 1.6 W/cm²) that are orthogonal to one another and intersect at the center of a 1 cm×1 cm square cuvette. In the case of photoswitchable photoinitiators including a spironaphthoxazine molecule or one of its derivatives, the light sources are (405 nm, 0.9 mW/cm²) and (638 nm, 2.8 W/cm²). The time taken to form the polymerized spot (“voxel time”) is noted and serves as a proxy for formation of a part in the printer. In a separate experiment, the resin is exposed to only 405 nm light, and the time required for cure (“light sheet time”) is noted. This serves as a proxy for cure from the UV light sheet in the printer. The [voxel/light sheet] times for NO17 and NP31 are [59 sec/168 sec] and [13 sec/20 sec], respectively. Exposures and measurements were carried out at room temperature (approximately 22° C.).

In the present work, the time difference between the formation of voxel and light sheet cure, determined as set forth in described in Example 4, was used as a metric for predicting the performance of a photoswitchable photoinitiator for volumetric printing in a resin formulation and using wavelengths and power levels that are the same or substantially similar to those described in the Example. A ratio of (time to cure UV light/time to cure voxel) of at least one (1) with a voxel cure time of 30 seconds or less, and preferably a ratio of (time for UV cure/time for voxel cure) of at least 1.2 and voxel cure time less than 15 seconds, under the conditions of Example 4, was found to be useful to screen for preferred photoswitchable photoinitiators for volumetric printing.

While not wishing to be bound by theory, it is believed that a ratio of (time to cure UV light/time to cure voxel) not greater than one or a cure time greater than 30 seconds is not to be interpreted as an indication that the particular photoswitchable photoinitiator is not suitable for use in volumetric printing. It is expected that such results may be useful as an indicator to vary one or more printing conditions (e.g., photoswitchable photoinitiator and/or synergist concentrations, power levels of one or both of the excitation light, printing temperature, and/or one or both of excitation wavelengths) for better printability. Such adjustments are routine for one of ordinary skill in the art without the need for undue experimentation.

### Example 5—Example of Procedure for Printing an Object

A cuvette of photohardenable composition (e.g., as described in Example 3) is placed in a plastic holder on a motorized stage. Red or green laser light (e.g., 638 nm or 532 nm CW diode laser, 10-40 W operating power) is used to illuminate a digital micromirror device (Texas Instruments) to form a pattern which is projected into the cuvette along the z axis to produce a pattern of approximately 1-10 W/cm² of red or green light, respectively. UV or violet light (e.g., 375 nm or 405 nm CW diode laser, 50-300 mW operating power) is used to form a light sheet that passes through the cuvette orthogonally to the projected pattern to illuminate a single x-y plane of nominal 100 microns thickness to produce an intensity of, for example, approximately 0.1-5 W/cm². The stage is advanced in increments of 1-100 microns at intervals of 50-5000 ms, with the UV or violet light forming a light sheet and the red or green light pattern changing at each advancement corresponding to computer generated slices of a three-dimensional object. In regions where there is simultaneous or nearly simultaneous exposure to both wavelengths of light, the photohardenable composition is hardened. In this manner, a three-dimensional solid object is formed without displacement (e.g., sinking or drifting) and without need for support structures or attachment to a build platform due to the high zero shear viscosity or yield stress of the non-Newtonian photohardenable composition.

Light sheets can be constructed by means known in the art including, for example, but not limited to, techniques including a laser and a Powell lens, galvanometer, and/or polygon scanning mirror. Alternatively, one or more LEDs can be used as a light source.

Information that may be useful in connection with inventions disclose herein include the x, y, z volumetric methods described in U.S. Pat. Nos. 4,041,476, 4,078,229, 4,238,840, 4,466,080, 4,471,470, and 4,333,165 to Swainson and in U.S. Pat. No. 5,230,986 to Neckers. Additional information that may be useful includes International Patent Application No. PCT/US2021/035791 of Quadratic 3D, Inc. filed Jun. 3, 2021 for “Volumetric Three-Dimensional Printing Methods Including A Light Sheet And Systems” and U.S. Pat. No. 10,843,410 of Lippert, et al. for “System And Method For A Three-Dimensional Optical Switch Display (OSD) Device”; and International Patent Application No. PCT/US2022/037491, filed Jul. 18, 2022, of Quadratic 3D, Inc. Each of the foregoing is hereby incorporated herein by reference in its entirety.

Before forming an object or “printing”, a digital file of the object to be printed is obtained. If the digital file is not of a format that can be used to print the object, the digital file is then converted to a format that can be used to print the object. An example of a typical format that can be used for printing is an STL file. Typically, the STL file is then sliced into two-dimensional layers with use of three-dimensional slicer software and converted into G-Code or a set of machine commands, which facilitates building the object. See B. Redwood, et al., “The 3D Printing Handbook—Technologies, designs applications”, 3D HUBS B.V. 2018.

As used herein, unless otherwise provided, “alkyl” refers to a branched or straight fully saturated acyclic aliphatic hydrocarbon group (i.e., composed of carbon and hydrogen containing no double or triple bonds). Examples include, but are not limited to, alkyl groups having 1 to 20 (more typically 1 to 10) carbon atoms which may be straight chain, or branched chain alkyl groups.

As used herein, unless otherwise provided, “alkoxy” refers to straight or branched chain alkyl moiety covalently bonded to the parent molecule through an —O— linkage. Examples include, but are not limited to, alkoxy groups having 1 to 20 (more typically 1 to 10) carbon atoms which may be straight chain, branched chain, or cyclic alkoxy groups, examples of which include, but are not limited to, methoxy (MeO), ethoxy (EtO), etc.

As used herein, unless otherwise provided, “aralkyl” or “arylalkyl” refers to an aryl-substituted alkyl moiety. Examples include, but are not limited to, aralkyl groups having 7 to 20 carbon atoms, examples of which include, but are not limited to, benzyl, methylphenyl, ethylphenyl, etc.

As used herein, unless otherwise provided, “cycloalkyl” refers to saturated aliphatic ring system moiety having, e.g., three to twenty carbon atoms. Examples include, but are not limited to, cyclopropyl, cyclopentyl, cyclohexyl, cycloheptyl, and the like.

As used herein, unless otherwise provided, “heteroalkyl” refers to an alkyl group comprising one or more heteroatoms. When two or more heteroatoms are present, they may be the same or different. Examples of heteroalkyl groups include, but are not limited to, CH₂—OH, O—CₙH.₂ₙ₊₁, where n is any integer greater than or equal to 1.

As used herein, unless otherwise provided, “aryloxy” refers to an aryl moiety covalently bonded to the parent molecule through an —O— linkage.

As used herein, unless otherwise provided, “heteroatom” refers to any atom that is not hydrogen or carbon. Typical heteroatoms include but are not limited to S (sulfur), N (nitrogen), O (oxygen), P (phosphorous), Cl (chlorine), Br (bromine), I (iodine), F (fluorine), etc.

As used herein, unless otherwise provided, “alkenyl” refers to a monovalent straight or branched chain moiety of from, e.g., two to twenty carbon atoms containing a carbon double bond. Examples include, but are not limited to, 1-propenyl, 2-propenyl, 2-methyl-1-propenyl, 1-butenyl, 2-butenyl, and the like.

As used herein, unless otherwise provided, “amido” refers to —NRC(═O)R′ wherein R and R′ can be the same of different, wherein R and R′ can independently represent, for example, for example, but not limited to, hydrogen, alkyl, or aryl.

As used herein, unless otherwise provided, “amino” refers to —NRR′ wherein R and R′ can independently represent, for example, but not limited to, hydrogen, alkyl, or aryl.

As used herein, unless otherwise provided, “carboxy ester” refers to —C(═O)O. Examples include groups of the structure —COOR or —OCOR wherein R can represent, for example, but not limited to, hydrogen, alkyl, or aryl.

As used herein, unless otherwise provided, “carboxyl” refers to —COOH.

As used herein, unless otherwise provided, “carbonyl” refers to C═O.

As used herein, unless otherwise provided, “aryl” refers to any aromatic carbocyclic or heterocyclic group containing unsaturated C—C bonds in conjugation with one another, whether one ring or multiple fused rings. Examples of aryl groups include, but are not limited to, an aryl group including, for example, 5 to 20 carbon atoms, examples of which include, but are not limited to, phenyl, naphthyl, phenanthryl, etc. Examples of “aryl” substituents include, but are not limited to phenyl, naphthyl, anthranyl, naphthacenyl, fluorenyl, pyrenyl, etc., or any aromatic heterocyclic group such as pyridine, pyrazine, indole, purine, furan, thiophene, pyrrole and the like.

As used herein, unless otherwise provided, “heteroaryl” may also refer to an aromatic ring system moiety in which one or more ring atoms are heteroatoms, whether one ring or multiple fused rings. When two or more heteroatoms are present, they may be the same or different. In fused ring systems, the one or more heteroatoms may be present in only one of the rings. Examples of heteroaryl groups include, but are not limited to, benzothiazyl, benzoxazyl, quinazolinyl, quinolinyl, isoquinolinyl, quinoxalinyl, pyridinyl, pyridazinyl, pyrimidinyl, pyrazinyl, pyrrolyl, oxazolyl, indolyl, thiazyl, and the like.

As used herein, unless otherwise provided, a “substituted” group, moiety, or molecule refers to a group, moiety, or molecule having at least one hydrogen that is substituted with a group of atoms or a non-hydrogen atom. (A group of atoms or non-hydrogen atom that replaces a hydrogen is also typically referred to as a substituent) When substituted, the substituent group(s) is (are) one or more group(s) individually and independently selected. Examples of various substituents include, but are not limited to, alkyl, cycloalkyl, alkenyl, cycloalkenyl, ether, aryl, heteroaryl, heterocycloalkyl, hydroxyl, oxy, alkoxyl, ester, thioester, acyl, carboxyl, carbonyl, cyano, nitro, amino, amido, halo (e.g., fluoro, chloro, bromo, iodo), or sulfur. When a substituted group includes more than one substituent, the substituents can be bound to the same atom in the group or two or more different atoms. A substituent including a group of atoms can optionally also be substituted.

When used as a characteristic of a portion of a container or build chamber, “optically transparent” refers to having high optical transmission to the wavelength of light being used, and “optically flat” refers to being non-distorting (e.g., optical wavefronts entering the portion of the container or build chamber remain largely unaffected).

As used herein, the singular forms “a”, “an” and “the” include plural unless the context clearly dictates otherwise. Thus, for example, reference to an emissive material includes reference to one or more of such materials.

Applicant specifically incorporates the entire contents of all patents, patent applications, publications, and other references cited or referenced in this disclosure. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed, as well as the upper and lower value of each range. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. A photoswitchable photoinitiator comprising a photochromic benzospiropyran molecule including one or more substituents at least one of which substituents includes a substituted or unsubstituted alpha-diketone moiety represented by general formula (I):
Ar¹—C(═O)—C(═O)—Ar² (I)
wherein Ar¹ and Ar² are the same or different and are independently a substituted or unsubstituted aryl group or a substituted or unsubstituted heteroaryl group.

2. The photoswitchable photoinitiator of claim 1 wherein the benzospiropyran molecule is represented by general formula (II): 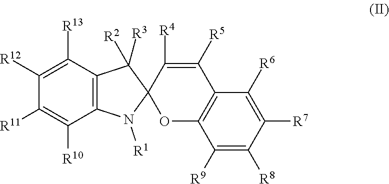
wherein R¹-R¹³ are the same or different and independently represent, for example, hydrogen, a substituted or unsubstituted alkyl group, a substituted or unsubstituted alkenyl group, a substituted or unsubstituted cycloalkenyl group, a substituted or unsubstituted cycloalkyl group, a substituted or unsubstituted aryl group, a substituted or unsubstituted aralkyl group, a substituted or unsubstituted alkylaryl group, a substituted or unsubstituted heteroaryl group, a substituted or unsubstituted aryloxy group, a substituted or unsubstituted alkoxy group, a substituted or unsubstituted ester group, a substituted or unsubstituted carbonate group, a substituted or unsubstituted ketone group, a substituted or unsubstituted aldehyde group, a substituted or unsubstituted imine group, a substituted or unsubstituted carboxyl group, a substituted or unsubstituted amido group, a substituted or unsubstituted urethane group, a substituted or unsubstituted urea group, a substituted or unsubstituted tetrazine group, a substituted or unsubstituted amino group, iodo, bromo, chloro, fluoro, a cyano group, a nitro group, a hydroxyl group, a thiol, an alkyl thioether, an aryl thioether, or a substituted or unsubstituted alcohol group, and
wherein at least one of R¹-R¹³ comprises the substituted or unsubstituted alpha-diketone moiety.

3. The photoswitchable photoinitiator of claim 1 wherein the substituted or unsubstituted alpha-diketone moiety is attached to the photochromic benzospiropyran molecule by a bond.

4. The photoswitchable photoinitiator of claim 1 wherein the substituted or unsubstituted alpha-diketone moiety is attached to the photochromic benzospiropyran molecule via a bond to a substituent on the photochromic molecule.

5. The photoswitchable photoinitiator of claim 1 wherein the substituted or unsubstituted aryl group included in each of Ar¹ and Ar² are the same or different and independently comprise an aromatic ring including but not limited to a benzene ring, a naphthalene ring, anthracene ring, indene ring, fluorene ring and others wherein the aryl group is substituted or unsubstituted.

6. The photoswitchable photoinitiator of claim 1 wherein the substituted or unsubstituted heteroaryl group included in each of Ar¹ and Ar² are the same or different and independently comprise a heteroaryl ring including but not limited to a furan ring, thiophene ring, pyrrole ring, oxazole ring, isooxazole ring, thiazole ring, isothiazole ring, imidazole ring, pyrazole ring, pyrane ring, pyridine ring, pyrazine ring, indole ring, quinoline ring, isoquinoline ring, xanthene ring, carbazole ring, acridine ring, indoline ring, julolidine ring and others wherein the heteroaryl group is substituted or unsubstituted.

7. The photoswitchable photoinitiator of claim 1 wherein a substituent on an aryl group and/or heteroaryl group comprises a halogen atom, alkyl, alkoxy, alkylamino, dialkylamino, alkylthio, heterocyclic groups, more specifically, hydrogen atom, methyl, ethyl, isopropyl, tert-butyl, phenyl, trifluoromethyl, cyano, acetyl, ethoxycarbonyl, carboxyl, carboxylate, amino, methylamino, dimethylamino, ethylamino, diethylamino, isopropylamino, diisopropylamino, cyclohexylamino, dicyclohexylamino, acetylamino, piperidino, pyrrolidyl, —PO₃H, methoxy, ethoxy, propoxy, isopropoxy, butoxy, pentyloxy, phenoxy, hydroxyl, acetoxy, methylthio, ethilthio, isopropylthio, mercapto, acetylthio, thiocyano, methylsulfinyl, methylsulfonyl, dimethylsulfonyl, sulfonate groups, fluorine atom, chlorine atom, bromine atom, iodine atom, trimethylsilyl, triethylsilyl, furyl, thienyl, pyridyl, piperidino, morpholino, pyrrolidyl groups, and the like.

8. The photoswitchable photoinitiator of claim 1 wherein the alpha-diketone moiety comprises a substituted or unsubstituted benzil group.

9-50. (canceled)

51. A photohardenable composition comprising a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component at the intersection of the lights of the two wavelengths, wherein the first and second wavelengths are different, and wherein the photoswitchable photoinitiator comprises a photochromic molecule comprising a benzospiropyran molecule including one or more substituents at least one of which comprises a substituted or unsubstituted alpha-diketone moiety represented by general formula (I):
Ar¹—C(═O)—C(═O)—Ar² (I)
wherein Ar¹ and Ar² are the same or different and are independently a substituted or unsubstituted aryl group or a substituted or unsubstituted heteroaryl group.

52-53. (canceled)

54. The photohardenable composition of claim 51 further comprising one or more coinitiators.

55-56. (canceled)

57. The photohardenable composition of claim 51 wherein the photohardenable resin component displays non-Newtonian rheological behavior.

58. The photohardenable composition of claim 54 wherein the coinitiator comprises a tertiary amine.

59. The photohardenable composition of claim 54 wherein the coinitiator comprises a borate salt.

60. The photohardenable composition of claim 54 wherein the coinitiator comprises an iodonium salt.

61-64. (canceled)

65. The photohardenable composition of claim 51 further comprising a second light activated photoinitiator, wherein the photoinitiator is not appreciably activated by light of the first wavelength and second wavelength.

66-70. (canceled)

71. A method of forming an object comprising:
(a) providing a volume including a photohardenable composition, wherein the photohardenable composition comprises a photohardenable resin component and a photoswitchable photoinitiator, wherein the photoswitchable photoinitiator is activatable by exposure to light having a first wavelength and light having a second wavelength to induce a crosslinking or polymerization reaction in the photohardenable resin component at the intersection of the lights of the two wavelengths, wherein the first and second wavelengths are different, and wherein the photoswitchable photoinitiator comprises a photochromic molecule comprising a benzospiropyran molecule including one or more substituents at least one of which comprises a substituted or unsubstituted alpha-diketone moiety represented by general formula (I):
Ar¹—C(═O)—C(═O)—Ar² (I)
wherein Ar¹ and Ar² are the same or different and are independently a substituted or unsubstituted aryl group or a substituted or unsubstituted heteroaryl group;
(b) simultaneously or sequentially irradiating one or more selected locations within the volume of the photohardenable composition with light having a first wavelength and light having a second wavelength, wherein light having the first wavelength and light having the second wavelength activate the photoswitchable photoinitiator at the one or more selected locations to induce a crosslinking or polymerization reaction in the photohardenable composition at the intersection of the first and second wavelengths at the one or more selected locations within the volume to at least partially form the object; and
(c) optionally repeating step b, irradiating the photohardenable composition at one or more of the same or different selected locations in the volume until the object is partially or fully formed.

72. (canceled)

73. The method of claim 71 wherein the photohardenable composition displays non-Newtonian rheological behavior.

74-76. (canceled)

77. The method of claim 71 wherein the photohardenable composition further includes a photoinitiator wherein the photoinitiator is not appreciably activated by light of the first wavelength and second wavelength and wherein the method further comprises a post curing step comprising exposing the object to light of a third wavelength to further harden the object, the third wavelength being different from the first and second wavelengths.

78-80. (canceled)

81. The method of claim 71 wherein the photoswitchable photoinitiator is activatable by exposure to light having a first wavelength and light having a second wavelength to induce a crosslinking or polymerization reaction in the photohardenable resin component, wherein the first and second wavelengths are different, and wherein the first wavelength is in a range from about 300 to about 550 nm and the second wavelength is in a range from about 450 to about 1000 nm.

82-102. (canceled)

103. The method of claim 71 wherein the object at least partially formed in the photohardenable composition remains at a fixed position or is minimally displaced in the unhardened photohardenable composition during formation.

104-105. (canceled)
